(19) United States
(12) Patent Application Publication
(10) Pub. No.: US 2025/0120197 A1
(43) Pub. Date: Apr. 10, 2025

(54) SEMICONDUCTOR DEVICE AND METHODS OF FORMATION

(71) Applicant: Taiwan Semiconductor Manufacturing Company, Ltd., Hsinchu (TW)

(72) Inventors: Ming-Hsien YANG, Taichung City (TW); Kun-Hui LIN, Tainan City (TW); Chun-Hao CHOU, Tainan City (TW); Kuo-Cheng LEE, Tainan City (TW)

(21) Appl. No.: 18/481,475

(22) Filed: Oct. 5, 2023

(51) Int. Cl. H01L 27/146; G01S 7/481; G01S 17/894

(52) U.S. Cl. CPC H10F 39/8027; G01S 7/4816; G01S 17/894; H10F 39/018; H10F 39/182; H10F 39/807; H10F 39/809

(57) ABSTRACT

A pixel sensor array may include a plurality of pixel sensors configured to generate color information associated with incident light, and a time of flight (ToF) sensor circuit configured to generate distance information associated with the incident light. The color information and the distance information may be used to generate a three-dimensional (3D) ToF color image. The ToF sensor circuit may be included under a DTI structure surrounding the plurality of pixel sensors in a top view of the pixel sensor array.

### BACKGROUND

A complementary metal oxide semiconductor (CMOS) image sensor may include a plurality of pixel sensors. A pixel sensor of the CMOS image sensor may include a transfer transistor, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1F are diagrams of example implementations of a time-of-flight (ToF) sensor circuit described herein.

FIG. 2 is a diagram of an example implementation of a ToF sensing operation performed by a ToF sensor circuit described herein.

FIGS. 3A and 3B are diagrams of example implementations of a ToF sensor circuit described herein.

FIGS. 4A-4F are diagrams of an example implementation of a pixel sensor array described herein.

FIGS. 5A-5F are diagrams of example implementations of a pixel sensor array described herein.

FIGS. 6A-6F are diagrams of example implementations of a pixel sensor array described herein.

FIGS. 7A-7K are diagrams of an example implementation of forming an image sensor device described herein.

FIGS. 8A and 8B are diagrams of example implementations of a pixel sensor array described herein.

FIG. 9 is a flowchart of an example process associated forming a pixel sensor array described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Time-of-flight (ToF) sensors (e.g., sensors that use germanium-on-silicon technology to enable depth sensing) can be used in a system designed to detect distances to objects in an area. Generally, a given ToF sensor detects a phase difference between a signal transmitted by the system and a corresponding signal received by the given ToF sensor (after reflection of the signal by an object in the area). This phase difference can be used to determine the distance to the object that reflected the signal. In some cases, outputs from an array of ToF sensors can be used to generate distance information that indicates distances to objects in an area.

Implementations described herein provide an image sensor that includes two-tap lock-in ToF sensor circuits and associated pixel sensor arrays. The ToF sensor circuits described herein are configured to use lateral electric field charge modulation (LEFM) and two-stage charge transfer techniques to generate distance information. The ToF sensor circuits may generate a sensing current that is modulated by operating and repeating a plurality of time windows (e.g., two time windows for two-tap lock-in ToF sensor circuits), and the modulated signals from the time windows are integrated in an integrator or a low-pass filter that may be implemented as charge accumulation of the sensing currents. The integration of the sensing currents may correspond to a correlation difference between the sensing currents and time window functions, which enables a time-dependent component to be generated as the distance information for each of the ToF sensor circuits. Each ToF sensor circuit may be configured to generate distance information for a relatively small sensing area (e.g., a sub-micron area), enabling high-speed modulation to be realized for the image sensor and enabling the distance information to be quickly generated (e.g., sub-nanosecond distance sensing).

Moreover, as described herein, a two-tap lock-in ToF sensor circuit described herein may be fabricated using CMOS processing techniques and may be integrated into a pixel sensor array to enable three-dimensional color images (or three-dimensional night-vision images) to be generated using distance information generated by the ToF sensor circuit. The ToF pixel sensor may include a plurality of control gates and one or more drain gates. The control gates and the drain gates may be located under a deep trench isolation (DTI) structure surrounding the pixel sensors of the pixel sensor array. The control gates may be used for applying the lateral electric field and for transferring a sensing current from the pixel sensors to respective floating diffusion regions. The draining gate(s) may be configured to drain unwanted charges from ambient light from the pixel sensors prior to generating the sensing current.

The control gates may be activated during different time windows to accumulate charges associated with the sensing current. The sensing current in the time windows may be modulated by operating and repeating the time windows, and the modulated signals from the time windows may be integrated in an integrator or a low-pass filter that may be implemented as charge accumulation of the sensing current to generate the distance information for the ToF pixel sensor.

In this way, the ToF sensor circuits described herein may be included in a CMOS image sensor (CIS) to achieve a time-resolved CIS. The time-resolved CIS may include the ToF sensor circuits and a plurality of visible light pixel sensors (e.g., a plurality of red-green-blue (RGB) pixel sensors) and/or infrared (IR) pixel sensors (e.g., near infrared (NIR) pixel sensors), among other examples. The outputs (e.g., the distance information) of the ToF pixel sensors and outputs of the visible light pixel sensors (e.g., image information) may be used to generate an image that indicates both distance to and colors of objects in an area (herein referred to as a three-dimensional (3D) ToF color image). That is, the time-resolved CIS described herein enables distance information determined by the ToF pixel sensors and color information determined by image pixel sensors to be combined to enable generation of a 3D ToF color image that indicates both distances to and colors of objects in an area.

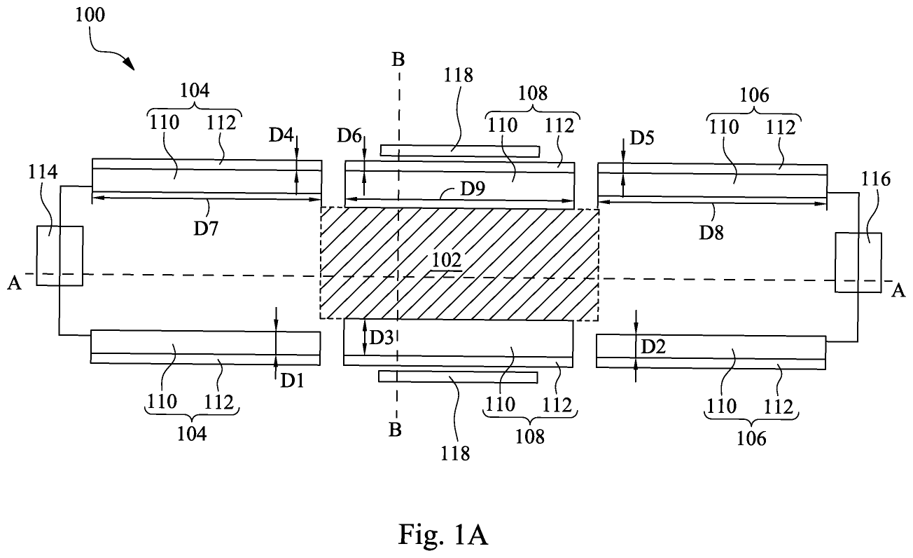

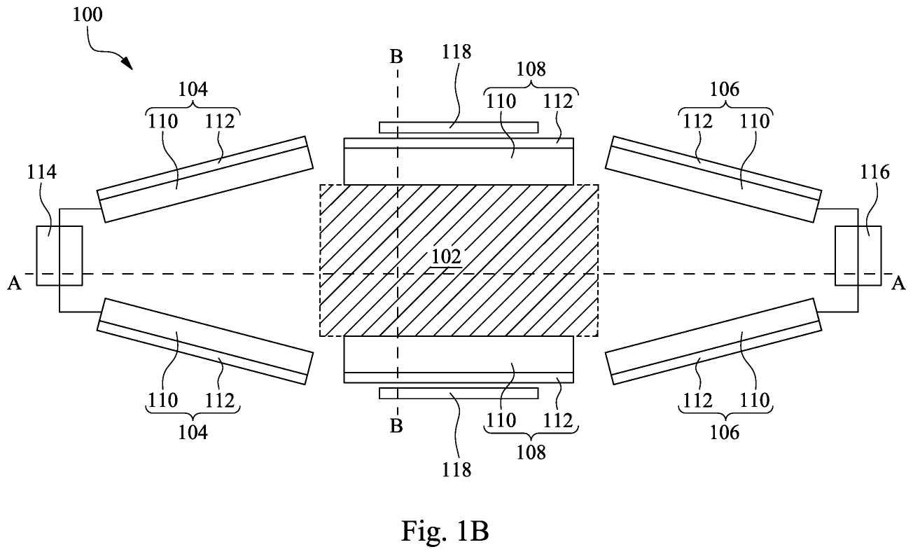

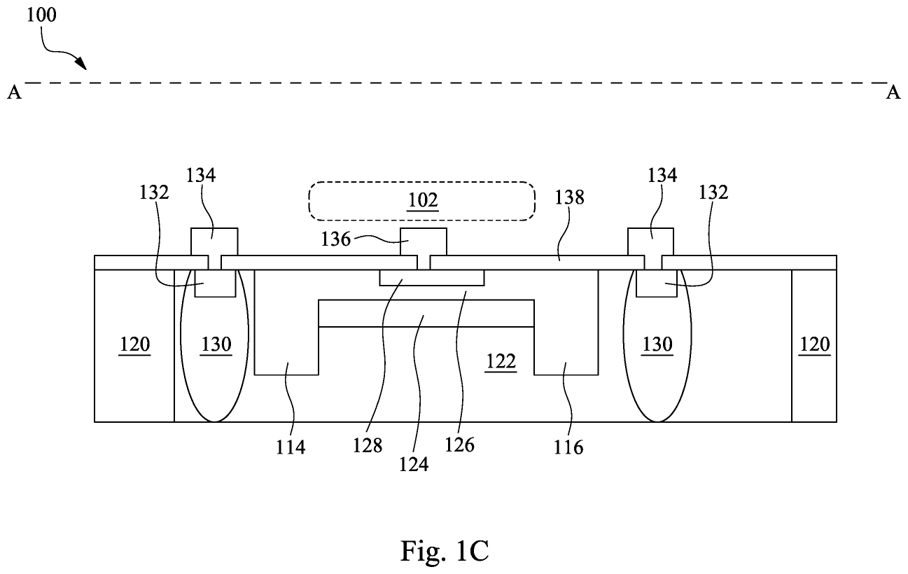

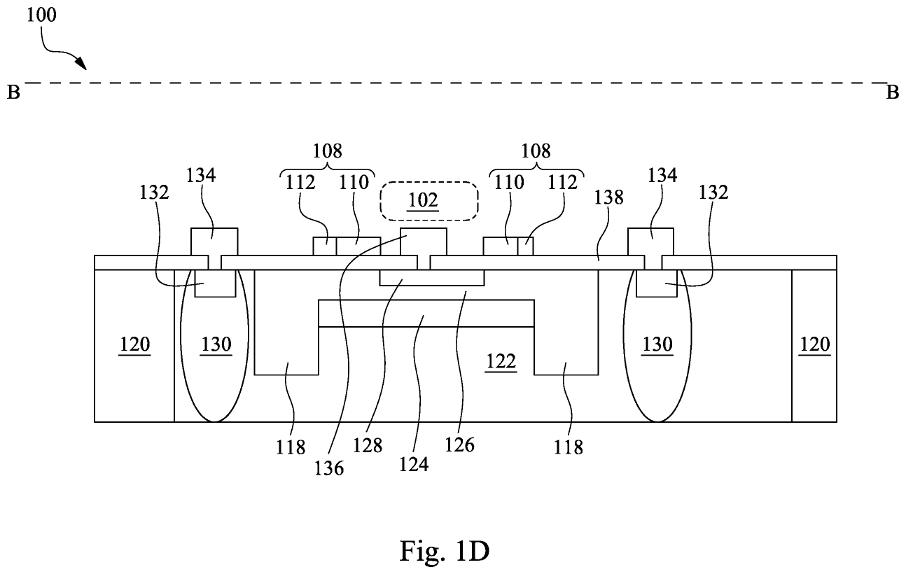

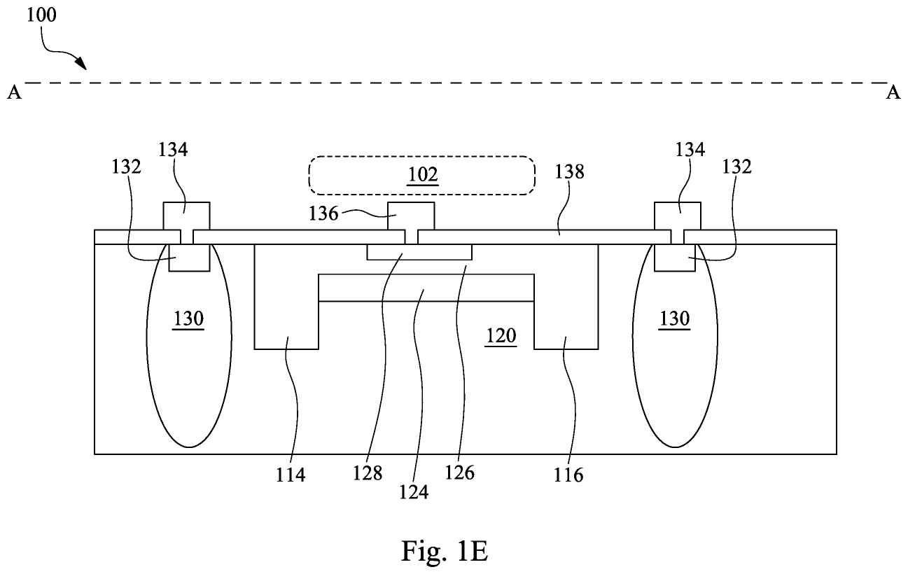

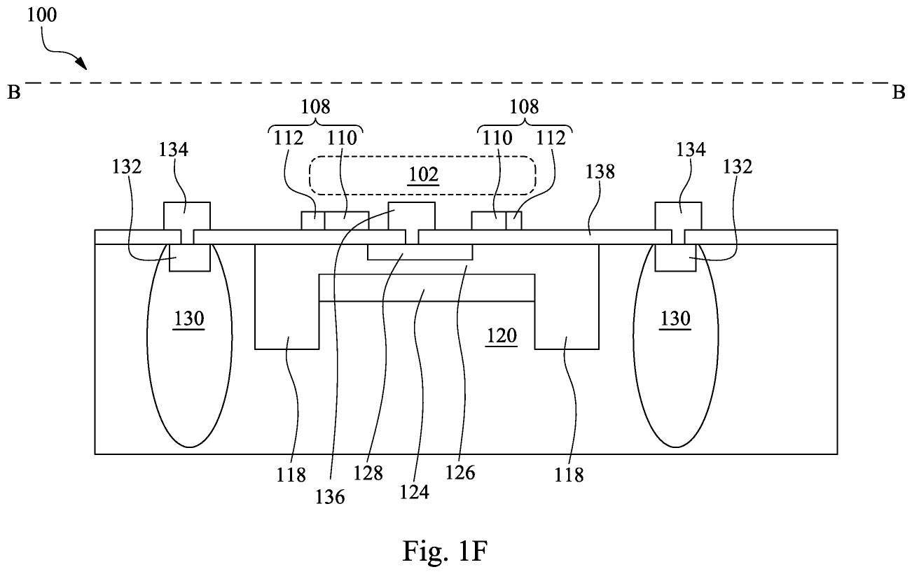

FIGS. 1A-1F are diagrams of example implementations of a ToF sensor circuit 100 described herein. The ToF sensor circuit 100 may be configured to generate distance information associated with incident light, such as a sensing current that indicates a roundtrip time or time of flight of the incident light.

FIG. 1A illustrates a top-down view of an example implementation of the ToF sensor circuit 100. As shown in FIG. 1A, the ToF sensor circuit 100 includes an aperture 102 through which the incident light is sensed by the ToF sensor circuit 100. The ToF sensor circuit 100 may include one or more control gates 104, one or more control gates 106, and one or more drain gates 108. In some implementations, a plurality of drain gates 108 are located on opposing sides of the aperture 102. The control gate(s) 104 may be located on a first side of the drain gate(s) 108, and the control gate(s) 106 may be located on a second side of the drain gate(s) 108. The first side and the second side may be opposing sides of the drain gate(s) 108.

As further shown in FIG. 1A, the control gate(s) 104, the control gate(s) 106, and the drain gate(s) 108 may each include a p-type portion 110 and an n-type portion 112. The p-type portion 110 may include a semiconductor material (e.g., silicon (Si), polysilicon) that is doped with one or more p-type dopants such as phosphorous (P) and/or arsenic (As), among other examples. The n-type portion 112 may include a semiconductor material that is doped with one or more n-type dopants such as boron (B) and/or indium (In), among other examples. The control gate(s) 104, the control gate(s) 106, and/or the drain gate(s) 108 may be implemented by field effect transistors (FETs), such as planar FETs, finFETs, nanostructure FETs (e.g., gate all around (GAA) FETs), and/or another type of FETs.

The control gate(s) 104 may be configured to control the flow of a sensing current toward a floating diffusion region 114 adjacent to the control gate(s) 104. The sensing current may be generated by the ToF sensor circuit 100 based on absorption of photons of the incident light. The control gate(s) 106 may be configured to control the flow of the sensing current toward a floating diffusion region 116 adjacent to the control gate(s) 106. The drain gate(s) 108 may be configured to drain the ToF sensor circuit 100 prior to sensing the incident light.

The ToF sensor circuit 100 may be configured to use LEFM and two-stage charge transfer techniques to generate the distance information. The sensing current generated by the ToF sensor circuit 100 may be modulated by controlling a lateral electric field between the floating diffusion regions 114 and 116. In particular, the control gates 104 and 106 may function as the taps for controlling the lateral electric field, and therefore the ToF sensor circuit 100 may be referred to as a two-tap lock-in ToF sensor circuit. For example, the sensing current may be transferred to the floating diffusion region 114 during a time window by activating the control gate(s) 104 while the control gate(s) 106 are deactivated, which slopes the lateral electric field toward the floating diffusion region 114. The sensing current may be transferred to the floating diffusion region 116 during another time window by activating the control gate(s) 106 while the control gate(s) 104 are deactivated, which slopes the lateral electric field toward the floating diffusion region 116. The drain gate(s) 108 may be activated while the control gates 104 and 106 are deactivated prior to the time windows to drain an underlying sensing region of the ToF sensor circuit 100 through drain region(s) 118 adjacent to drain gate(s) 108 to remove any residual charges from ambient light.

A width of a p-type portion 110 of a control gate 104 (corresponding to dimension D1 in FIG. 1A) and a width of a p-type portion 110 of a control gate 106 (corresponding to dimension D2 in FIG. 1A) may be approximately the same width to facilitate uniform sensing current modulation in the ToF sensor circuit 100. Moreover, the width of the p-type portion 110 of the control gate 104 and the width of the p-type portion 110 of the control gate 106 may be less than a width of a p-type portion 110 of a drain gate 108 (corresponding to dimension D3 in FIG. 1A) to facilitate high-speed and lossless charge modulation of the sensing current generated by the ToF sensor circuit 100. For example, a ratio of the widths of the p-type portions 110 of the control gates 104 and 106 to the width of the p-type portion 110 of the drain gate 108 (D1: D3 and D2: D3) may be included in a range of greater than 1:1 to approximately 1:1000 to achieve a low slope for the lateral electric field generated in the ToF sensor circuit 100, which facilitates high-speed and low-leakage charge modulation of the sensing current generated by the ToF sensor circuit 100. However, other values for the range are within the scope of the present disclosure.

A width of an n-type portion 112 of a control gate 104 (corresponding to dimension D4 in FIG. 1A) and a width of an n-type portion 112 of a control gate 106 (corresponding to dimension D5 in FIG. 1A) may be approximately the same width to facilitate uniform sensing current modulation in the ToF sensor circuit 100. Moreover, the width of the p-type portion 110 of the control gate 104 and/or the width of the n-type portion 112 the control gate 106 may be less than a width of an n-type portion 112 of a drain gate 108 (corresponding to dimension D6 in FIG. 1A) to facilitate high-speed and low-leakage charge modulation of the sensing current generated by the ToF sensor circuit 100. For example, a ratio of the width of the n-type portions 112 of the control gates 104 and 106 to the width of the n-type portion 112 of the drain gate 108 (D4: D6 and D5: D6) may be included in a range of greater than 1:1 to approximately 1:1000 to achieve a low slope for the lateral electric field generated in the ToF sensor circuit 100, which facilitates high-speed and lossless charge modulation of the sensing current generated by the ToF sensor circuit 100. However, other values for the range are within the scope of the present disclosure.

A ratio of the width of a p-type portion 110 of a control gate 104 to the width of an n-type portion 112 (D1: D4) of the control gate 104 may be in a range of approximately 1:1 to approximately 1:1000 to achieve a low slope for the lateral electric field generated in the ToF sensor circuit 100, which facilitates high-speed and low-leakage charge modulation of the sensing current generated by the ToF sensor circuit 100. However, other values for the range are within the scope of the present disclosure. A ratio of the width of a p-type portion 110 of a control gate 106 to the width of an n-type portion 112 of the control gate 106 (D2: D5) may be in a range of approximately 1:1 to approximately 1:1000 to achieve a low slope for the lateral electric field generated in the ToF sensor circuit 100, which facilitates high-speed and low-leakage charge modulation of the sensing current generated by the ToF sensor circuit 100. However, other values for the range are within the scope of the present disclosure. A ratio of the width of a p-type portion 110 of a drain gate 108 to the width of an n-type portion 112 of the drain gate 108 (D3: D6) may be in a range of approximately 1:1 to approximately 1:1000 to achieve a low slope for the lateral electric field generated in the ToF sensor circuit 100, which facilitates high-speed and low-leakage charge modulation of the sensing current generated by the ToF sensor circuit 100. However, other values for the range are within the scope of the present disclosure.

A length of a control gate 104 (corresponding to dimension D7 in FIG. 1A) and a length of a control gate 106 (corresponding to dimension D8 in FIG. 1A) may be approximately the same length to facilitate uniform sensing current modulation in the ToF sensor circuit 100. Moreover, the length of the control gate 104 and the length of the control gate 106 may be less than a length of a drain gate 108 (corresponding to dimension D9 in FIG. 1A) to facilitate high-speed and low-leakage charge modulation of the sensing current generated by the ToF sensor circuit 100. For example, a ratio of the lengths of the control gates 104 and 106 to the length of the drain gate 108 (D7: D9 and D8: D9) may be included in a range of greater than 1:1 to approximately 1:1000 to achieve a low slope for the lateral electric field generated in the ToF sensor circuit 100, which facilitates high-speed and lossless charge modulation of the sensing current generated by the ToF sensor circuit 100. However, other values for the range are within the scope of the present disclosure.

A ratio of the length of a p-type portion 110 of a control gate 104 to the length of an n-type portion 112 of the control gate 104 may be in a range of approximately 1:1 to approximately 1:1000 to achieve a low slope for the lateral electric field generated in the ToF sensor circuit 100, which facilitates high-speed and low-leakage charge modulation of the sensing current generated by the ToF sensor circuit 100. However, other values for the range are within the scope of the present disclosure. A ratio of the length of a p-type portion 110 of a control gate 106 to the length of an n-type portion 112 of the control gate 106 may be in a range of approximately 1:1 to approximately 1:1000 to achieve a low slope for the lateral electric field generated in the ToF sensor circuit 100, which facilitates high-speed and low-leakage charge modulation of the sensing current generated by the ToF sensor circuit 100. However, other values for the range are within the scope of the present disclosure. A ratio of the length of a p-type portion 110 of a drain gate 108 to the width of an n-type portion 112 of the drain gate 108 may be in a range of approximately 1:1 to approximately 1:1000 to achieve a low slope for the lateral electric field generated in the ToF sensor circuit 100, which facilitates high-speed and low-leakage charge modulation of the sensing current generated by the ToF sensor circuit 100. However, other values for the range are within the scope of the present disclosure.

FIG. 1B illustrates an alternative implementation in which the control gate(s) 104 and the control gate(s) 106 are angled in the ToF sensor circuit 100. This reduces the distance between the floating diffusion regions 114 and 116, which may further facilitate high-speed and low-leakage charge modulation of the sensing current generated by the ToF sensor circuit 100.

FIG. 1C illustrates a cross-sectional view of the ToF sensor circuit 100 along line A-A in FIGS. 1A and 1B. As shown in FIG. 1C, the ToF sensor circuit 100 may include a substrate 120, a deep well 122 in the substrate 120, a doped region 124 in the deep well 122, a doped well 126 in the deep well 122, a doped region 128 over the doped well 126, a doped guard ring 130 in the deep well 122 and around the doped region 124, and a doped region 132 over the doped guard ring 130. The doped region 132 may include a ring-shaped region with a shape similar to the shape of the doped guard ring 130.

The doped region 124, the doped well 126, and the doped region 128 may be a single-photon avalanche diode (SPAD) cell of the ToF sensor circuit 100. In particular, in the example illustrated in FIG. 1C, the SPAD cell may be a P′N high voltage input/output (I/O) SPAD cell in which the substrate 120 is a p-type substrate, the deep well 122 is a deep n-type well, the doped region 124 is an n-type doped region, the doped well 126 is a p-type doped well, the doped region 128 is a p-type doped region, the doped guard ring 130 is a deep n-type pinned photodiode region (DNPPD), and the doped region 132 is an n-type doped region. The aperture 102 may be included over the doped regions 124 and 128, and the floating diffusion regions 114 and 116 may be included in the doped well 126.

As further shown in FIG. 1C, the doped region 132 may be coupled with contacts 134, and the doped region 128 may be coupled with a contact 136. The contacts 134 and 136 may extend through a dielectric layer 138 on the substrate 120. The contacts 134 and 136 may include tungsten (W), cobalt (Co), titanium (Ti), copper (Cu), gold (Au), silver (Ag), molybdenum (Mo), ruthenium (Ru), a metal alloy, and/or another type of electrically conductive material, among other examples. The dielectric layer 138 may include a silicon oxide (SiOₓ), a silicon nitride (SiₓN_{y}), a silicon carbide (SiCₓ), or a mixture thereof, such as a silicon carbon nitride (SiCN), or a silicon oxynitride (SiON), among other examples.

FIG. 1D illustrates a cross-sectional view of the ToF sensor circuit 100 along line B-B in FIGS. 1A and 1B. As shown in FIG. 1D, the drain regions 118 may be included in the doped well 126, and the drain gates 108 may be included over the doped well 126 and over the dielectric layer 138.

FIGS. 1E and 1F illustrate an alternative implementation of the ToF sensor circuit 100 to the implementation illustrated and described in connection with FIGS. 1C and 1D. In the implementation of the ToF sensor circuit 100 in FIGS. 1E and 1F, the SPAD cell may be an N′P high voltage I/O SPAD cell in which the substrate 120 is a p-type substrate, the deep well 122 is omitted, the doped region 124 is a p-type doped region, the doped well 126 is an n-type doped well, the doped region 128 is an n-type doped region, the doped guard ring 130 is a deep p-well global guard ring, and the doped region 132 is a p-type doped region.

As indicated above, FIGS. 1A-1F are provided as examples. Other examples may differ from what is described with regard to FIGS. 1A-1F.

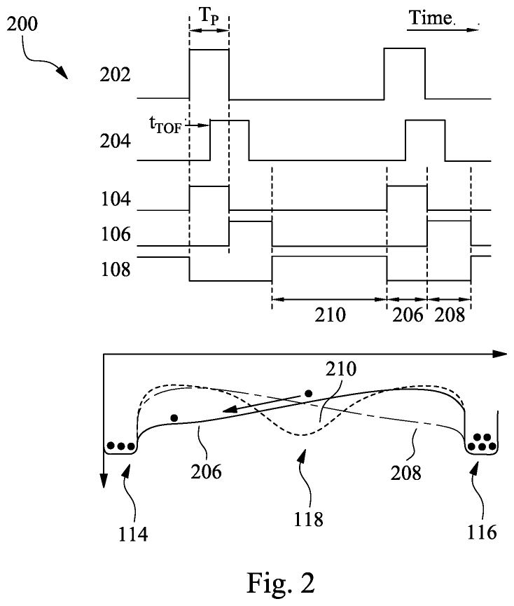

FIG. 2 is a diagram of an example implementation 200 of a ToF sensing operation performed by a ToF sensor circuit 100 described herein. As shown in FIG. 2, emitted light 202 is emitted from the ToF sensor circuit 100 for a time duration T_{P}. Received light 204 (which is at least a portion of the emitted light 202 reflected off of an object) is received at the ToF sensor circuit 100 after a ToF duration t_{ToF}. The distance L between the ToF sensor circuit 100 and the object may be determined as:

$$L = \frac{c {T}_{P}}{2} \cdot \frac{{S}_{FD 1}}{{S}_{FD 1} + {S}_{FD 2}}$$

where S_{FD1} is the sensing current generated based on a portion of the received light 204 during a sensing window 206, and S_{FD2} is the sensing current generated based on another portion of the received light 204 during another sensing window 208. During the sensing window 206, the control gate 104 may be activated, and the control gate 106 and the drain gate 108 may both be deactivated. This causes the lateral electric field to slope toward the floating diffusion region 114, which enables the sensing current to be accumulated in the floating diffusion region 114 for the sensing window 206. During the sensing window 208, the control gate 106 may be activated, and the control gate 104 and the drain gate 108 may both be deactivated. This causes the lateral electric field to slope toward the floating diffusion region 116, which enables the sensing current to be accumulated in the floating diffusion region 116 for the sensing window 208. Prior to the sensing windows 206 and 208, the drain gate 108 may be activated (and the control gates 104 and 106 may be deactivated) for a draining window 210 in which residual charges are drained to the drain region 118.

As indicated above, FIG. 2 is provided as an example. Other examples may differ from what is described with regard to FIG. 2.

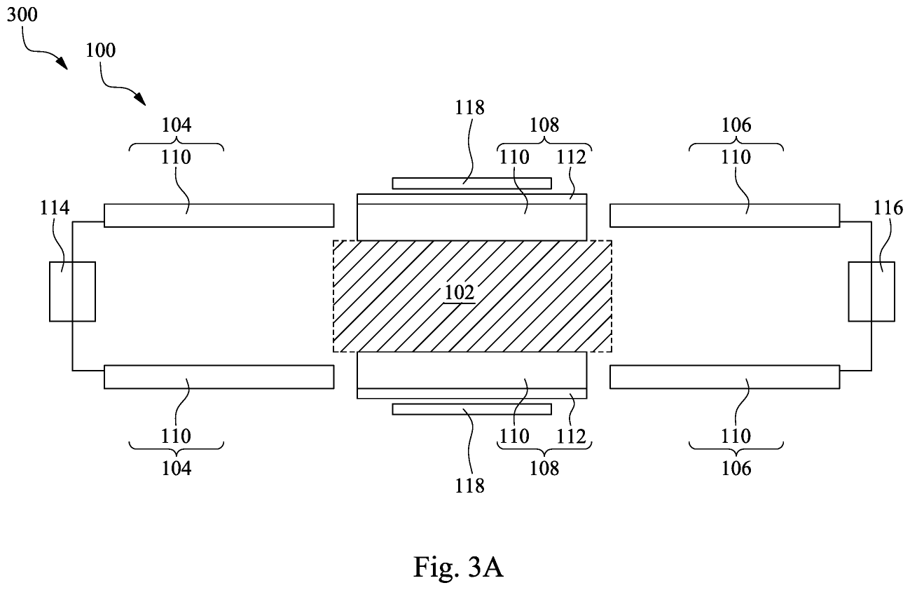

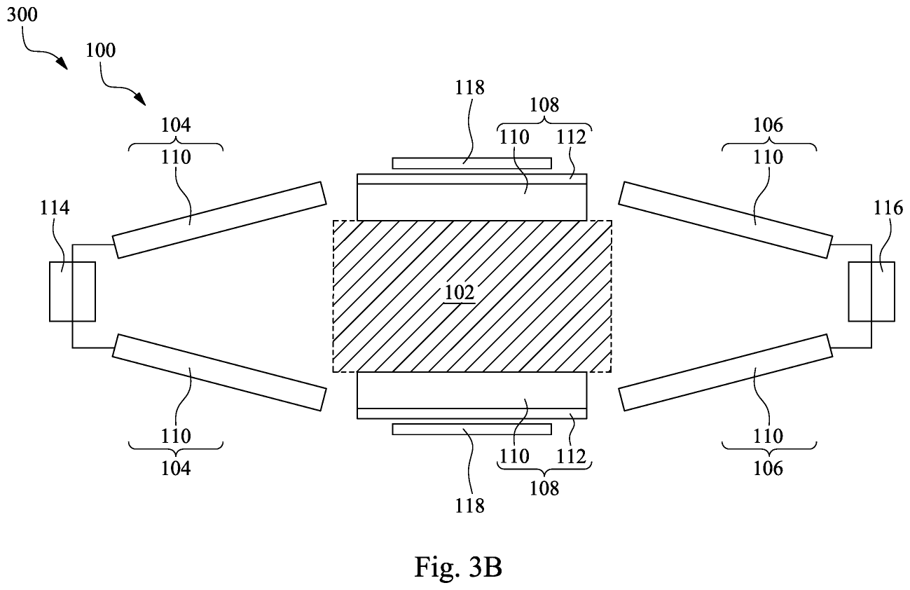

FIGS. 3A and 3B are diagrams of example implementations 300 of a ToF sensor circuit 100 described herein. FIG. 3A illustrates an example implementation similar to the example implementation in FIG. 1A, except that the n-type portions 112 are omitted from the control gate(s) 104 and the control gate(s) 106, which reduces the complexity of manufacturing the ToF sensor circuit 100 while still achieving sufficient lateral electric field control for the ToF sensor circuit. FIG. 3B illustrates an example implementation similar to the example implementation in FIG. 1B, except that the n-type portions 112 are omitted from the control gate(s) 104 and the control gate(s) 106, which reduces the complexity of manufacturing the ToF sensor circuit 100 while still achieving sufficient lateral electric field control for the ToF sensor circuit.

As indicated above, FIGS. 3A and 3B are provided as examples. Other examples may differ from what is described with regard to FIGS. 3A and 3B.

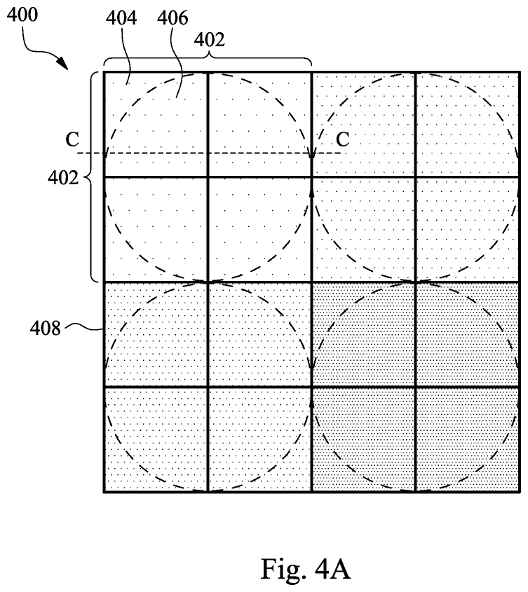

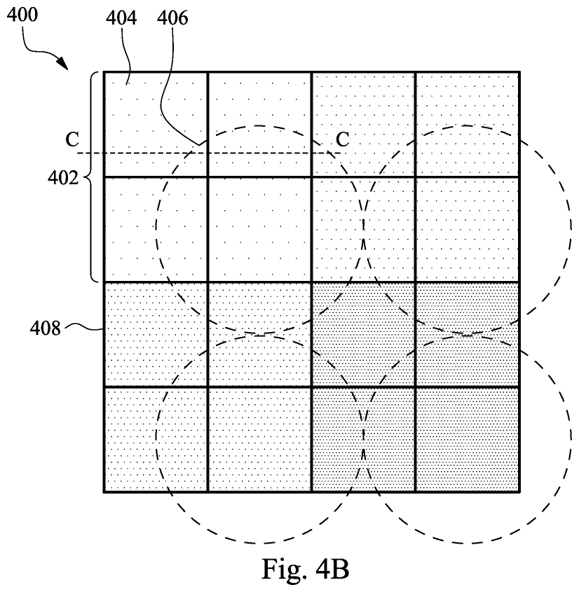

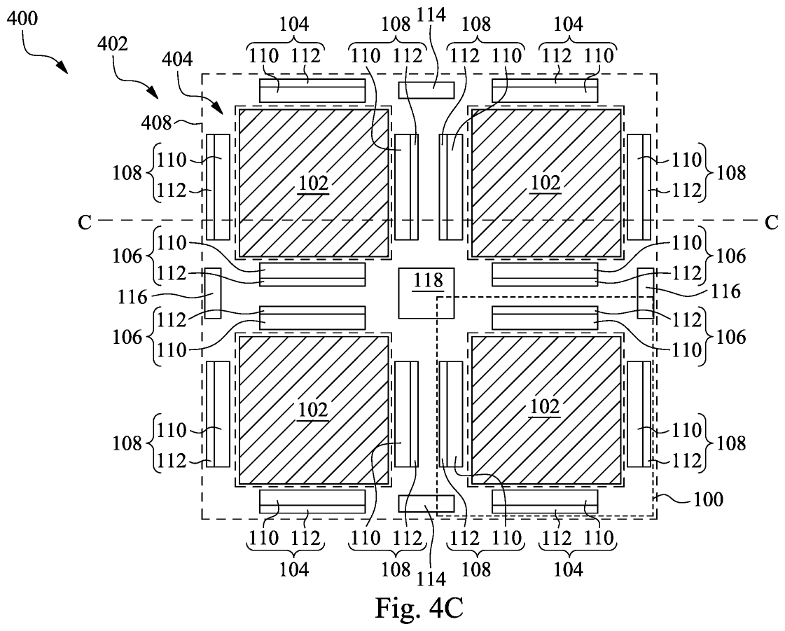

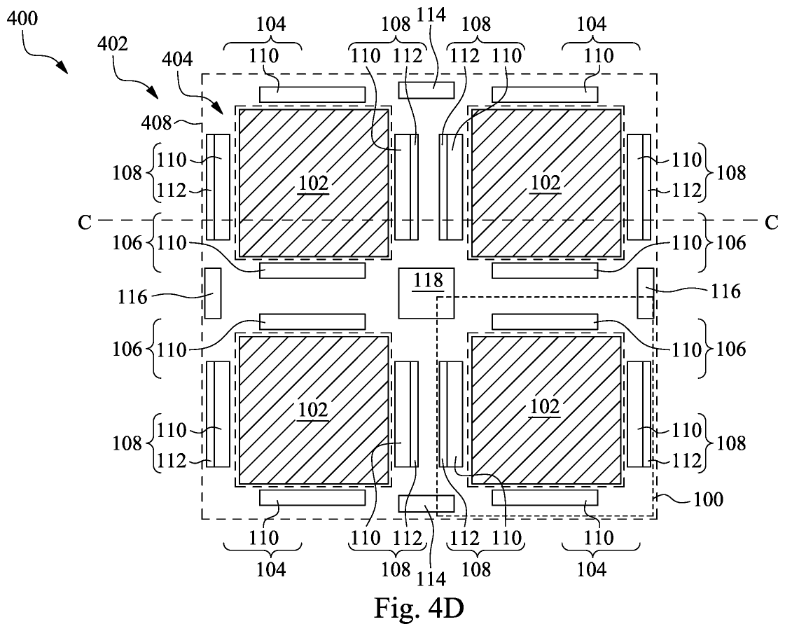

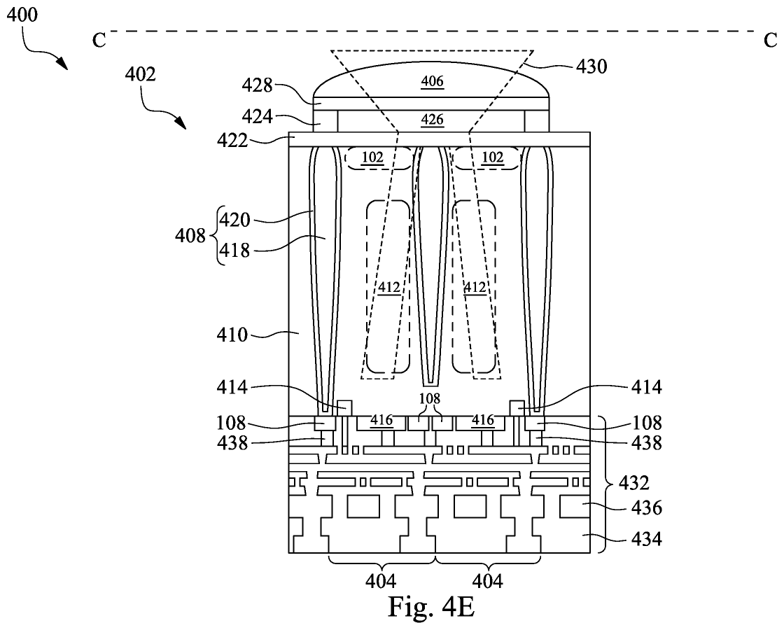

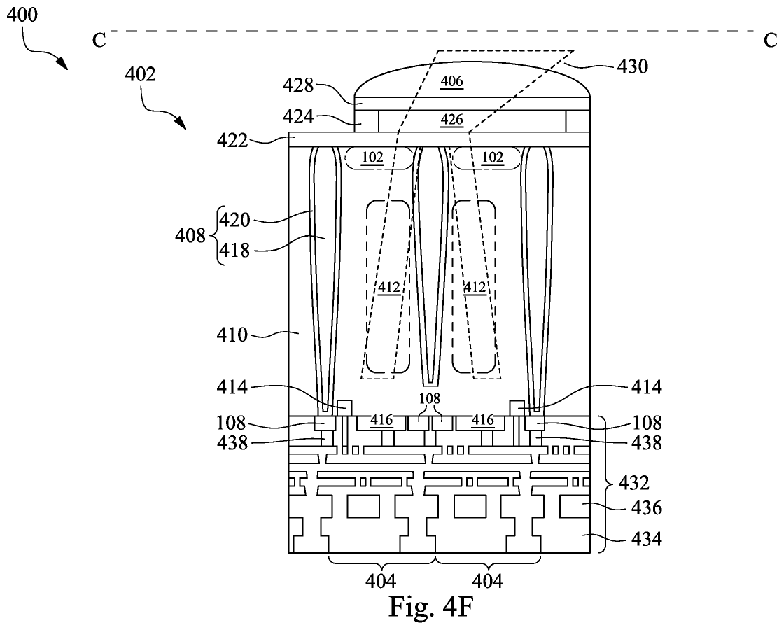

FIGS. 4A-4F are diagrams of an example implementation of a pixel sensor array 400 described herein. The pixel sensor array 400 may be included on a sensor die of an image sensor device, such as a CIS device or a time-resolved CIS device.

FIG. 4A illustrates a top-down view of the pixel sensor array 400. As shown in FIG. 4A, the pixel sensor array 400 includes a plurality of pixel sensors 402 that are configured to generate photocurrents for generating images and/or video. The pixel sensors 402 may be arranged in a grid. In some implementations, at least a subset of the pixel sensors 402 is configured to absorb photons of light in a particular wavelength range of visible light (e.g., red light, blue light, or green light) and to generate color information (e.g., a photocurrent corresponding to an intensity of an associated wavelength of incident light corresponding to a particular color). For example, one or more first pixel sensors 402 may be configured to absorb photons of light in a particular wavelength range of visible light corresponding to green light, one or more second pixel sensors 402 may be configured to absorb photons of light in a particular wavelength range of visible light corresponding to red light, one or more third pixel sensors 402 may be configured to absorb photons of light in a particular wavelength range of visible light corresponding to blue light, and so on. In some implementations, one or more pixel sensors 402 may be configured to absorb photons of non-visible light, such as photons of light in a wavelength range corresponding to IR or NIR.

In some implementations, the pixel sensor array 400 may include groups or regions of pixel sensors 402 that are configured for quadratic photodetection. As an example, the portion of the pixel sensor array 400 illustrated in FIG. 4A may be referred to as a 4-cell (4C) quadratic phase detector (QPD) region, and the pixel sensors 402 in the QPD region may be QPD pixel sensors. The pixel sensor array 400 may include one or more of the 4-cell QPD regions illustrated in FIG. 4A. A pixel sensor 402 in the 4-cell QPD region may include a plurality of subregions 404 and a micro lens (e.g., a single micro lens) 406 over the plurality of subregions 404. Each subregion 404 of a pixel sensor 402 may include a photodiode that is configured to generate a photocurrent based on photon absorption in the photodiode. The photocurrents generated by the photodiodes in the subregions 404 of a pixel sensor 402 may be binned such that a single unified photocurrent is provided from the pixel sensor 402 to circuitry on an associated circuitry die of the image sensor device.

The pixel sensors 402 may be electrically and optically isolated by a deep trench isolation (DTI) structure 408 included in the pixel sensor array 400. The DTI structure 408 may include a plurality of interconnected and intersecting trenches that are filled with one or more types of materials, such as a dielectric material (e.g., an oxide-containing material, a high dielectric constant (high-k) dielectric material), a polysilicon material, and/or another type of material. The DTI structure 408 may be included around the perimeters of the pixel sensors 402 such that the DTI structure 408 surrounds the pixel sensors 402 in a grid shape. Moreover, the DTI structure 408 may surround the subregions 404 of a pixel sensor 402 (and the photodiodes and drain regions included therein), as shown in FIG. 4A. The DTI structure 408 may extend into a substrate of the pixel sensor array 400 and may extend downward into the substrate along at least a portion of the photodiodes of the pixel sensors 402 included in the pixel sensor array 400.

FIG. 4B illustrates a top-down view of an alternative implementation in which the micro lenses 406 are offset (or off-centered) relative to the other structures of the pixel sensors 402. The offset micro lenses 406 enable the pixel sensor array 400 to be used in implementations in which incident light is directed toward the pixel sensors 402 at an angle (e.g., the incident light is received off-axis) in a manner that increases photon absorption, quantum efficiency (QE), and/or full well conversion (FWC) for the pixel sensors 402.

As shown in top-down views in FIGS. 4C and 4D, the pixel sensor array 400 may include one or more ToF sensor circuits 100 that are configured to generate distance information associated with incident light (e.g., a sensing current indicating a roundtrip time of travel of the incident light). The combination of the color information generated by the pixel sensors 402 and the distance information generated by the ToF sensor circuit(s) 100 may be used to generate a 3D ToF color image. In some implementations, a plurality of ToF sensor circuits 100 may be included under the DTI structure 408 and around the perimeter of a pixel sensor 402. For example, a ToF sensor circuit 100 may be included around each subregion 404 of the pixel sensor 402. This enables the ToF sensor circuits 100 to generate distance information for each subregion 404 of the pixel sensor 402.

As shown in FIGS. 4C and 4D, the control gates 104 and 106 of a ToF sensor circuit 100 may be located on opposing sides of the subregion 404 of the pixel sensor 402. The aperture 102 of the ToF sensor circuit 100 may correspond to an opening through the DTI structure 408. The drain gates 108 of the ToF sensor circuit 100 may be located on opposing sides of the subregion 404 of the pixel sensor 402 such that the control gate 104 and the drain gates 108 are on adjacent sides of the subregion 404 of the pixel sensor 402, and the control gate 106 and the drain gates 108 are on adjacent sides of the subregion 404 of the pixel sensor 402. In the example implementation in FIG. 4C, the control gates 104 and 106, and the drain gates 108, of the ToF sensor circuits 100, include both a p-type portion 110 and an n-type portion 112. In the example implementation in FIG. 4D, the n-type portions 112 are omitted from the control gates 104 and 106, and included only in the drain gates 108.

As further shown in FIGS. 4C and 4D, floating diffusion regions 114 and 116 of the ToF sensor circuits 100 surrounding the subregions 404 of the pixel sensor 402 may be shared by two or more ToF sensor circuits 100. For example, floating diffusion regions 114 may be shared and included in ToF sensor circuits 100 surrounding adjacent subregions 404 of the pixel sensor 402. As another example, floating diffusion regions 116 may be shared and included in ToF sensor circuits 100 surrounding adjacent subregions 404 of the pixel sensor 402. In some implementations, a subregion 404 of the pixel sensor 402 may share a floating diffusion region 114 with a first adjacent subregion 404, and may share a floating diffusion region 116 with a second adjacent subregion 404 different from the first adjacent subregion 404.

A floating diffusion region 114 of a ToF sensor circuit 100 may be located at a first corner of a subregion 404 of a pixel sensor 402 between a control gate 104 and a drain gate 108, and a floating diffusion region 116 of the ToF sensor circuit 100 may be located at a second corner of the subregion 404 opposing the first corner and between a control gate 106 and another drain gate 108. The floating diffusion regions 114 of the ToF sensor circuits 100 surrounding the subregions 404 of the pixel sensor 402 may be located on opposing sides of the pixel sensor 402. A floating diffusion region 114 may be located between control gates 104 of adjacent ToF sensor circuits 100 surrounding the subregions 404 of the pixel sensor 402, and may be located next to ends of drain gates 108 of the adjacent ToF sensor circuits 100. The floating diffusion regions 116 of the ToF sensor circuits 100 surrounding the subregions 404 of the pixel sensor 402 may be located on opposing sides of the pixel sensor 402. A floating diffusion region 116 may be located between drain gates 108 of adjacent ToF sensor circuits 100 surrounding the subregions 404 of the pixel sensor 402, and may be located next to ends of control gates 106 of the adjacent ToF sensor circuits 100. A floating diffusion region 114 and a floating diffusion region 116 may be located on adjacent sides of the pixel sensor 402.

As further shown in FIGS. 4C and 4D, the ToF sensor circuits 100 surrounding the subregions 404 of the pixel sensor 402 may all share the same drain region 118. Thus, a single drain region 118 may be associated with the pixel sensor 402. The drain region 118 may be located at a cross-road region of the pixel sensor 402 where four corners of the subregions 404 meet. The drain region 118 may be located next to ends of the control gates 106 of the ToF sensor circuits 100, and next to ends of a subset of the drain gates 108 of the ToF sensor circuits 100.

FIG. 4E illustrates a cross-section view, along the line C-C illustrated in FIGS. 4A, 4C, and 4D, of an example pixel sensor 402 in the 4-cell QPD region of the pixel sensor array 400 illustrated in FIG. 4A. As shown in FIG. 4E, the pixel sensor 402 may include a plurality of subregions 404. The subregions 404 may be arranged in a horizontally adjacent or side-by-side configuration in a substrate 410 of the pixel sensor array 400. The substrate 410 may include a semiconductor die substrate, a semiconductor wafer, a stacked semiconductor wafer, or another type of substrate in which semiconductor pixels may be formed. In some implementations, the substrate 410 is formed of silicon (Si) (e.g., a silicon substrate), a material including silicon, a III-V compound semiconductor material such as gallium arsenide (GaAs), a silicon on insulator (SOI), or another type of semiconductor material that is capable of generating a charge from photons of incident light. In some implementations, the substrate 410 is formed of a doped material (e.g., a p-doped material or an n-doped material), such as a doped silicon.

Each of the subregions 404 may include a respective photodiode 412 that is included in the substrate 410. The photodiodes 412 may include a plurality of regions that are doped with various types of ions to form a p-n junction or a PIN junction (e.g., a junction between a p-type portion, an intrinsic (or undoped) type portion, and an n-type portion). For example, the substrate 410 may be doped with an n-type dopant to form one or more n-type regions of a photodiode 412, and the substrate 410 may be doped with a p-type dopant to form a p-type region of the photodiode 412. A photodiode 412 may be configured to absorb photons of incident light that enter the substrate 410 through the apertures 102. The absorption of photons causes the photodiode 412 to accumulate a charge (referred to as a photocurrent) due to the photoelectric effect. Photons may bombard the photodiode 412, which causes emission of electrons in the photodiode 412. The photocurrent generated by a photodiode 412 may be transferred and/or stored in an associated drain region 414 in the substrate 410. A drain region 414 may include a doped portion (e.g., an n-doped portion, a p-doped portion) of the substrate 410.

The regions included in a photodiode 412 may be stacked and/or vertically arranged. For example, the p-type region may be included over the one or more n-type regions. The p-type region may provide noise isolation for the one or more n-type regions and may facilitate photocurrent generation in the photodiode 412. In some implementations, the p-type region (and thus, the photodiode 412) is spaced away from a frontside surface of the substrate 410 to provide noise isolation and/or light-leakage isolation from one or more metallization layers of the pixel sensor array 400.

As further shown in FIG. 4E, each of the subregions 404 may include a transfer gate 416. A transfer gate 416 may be located at a frontside surface of the substrate 410. A transfer gate 416 in a subregion 404 of the pixel sensor 402 may be configured to transfer the photocurrent generated by the photodiode 412 of the subregion 404 to a drain region 414 of the subregion 404. A transfer gate 416 may be implemented by a FET, such as a planar FET, a finFET, a nanostructure FET (e.g., a GAA FET), and/or another type of FET.

The pixel sensor array 400 may include a plurality of regions and/or structures that are configured to provide electrical isolation and/or optical isolation between the photodiodes 412 of the subregions 404 of the pixel sensor 402 and/or between the pixel sensor 402 and adjacent pixel sensors 402 in the pixel sensor array 400. For example, the pixel sensor array 400 may include the DTI structure 408 that includes a grid-shaped structure that extends into the substrate 410 and around the photodiodes 412 of the subregions 404 of the pixel sensors 402 included in the pixel sensor array 400.

The DTI structure 408 may include one or more trenches that extend downward into the substrate 410. The trenches may extend into the substrate 410 from a backside surface of the substrate 410 opposing the frontside surface. Thus, the pixel sensor array 400 may be referred to as a backside illuminated (BSI) pixel sensor array in that photons enter the photodiodes 412 from the backside surface of the substrate 410. Thus, the DTI structure 408 may be referred to as a backside DTI (BDTI) structure. Alternatively, the DTI structure 408 may include a frontside DTI (FDTI) structure that extends into the substrate from the front surface of the substrate 410. The DTI structure 408 may fully extend through the substrate 410 from the backside surface to the frontside surface to provide full isolation between adjacent pixel sensors 402. However, a portion of the substrate 410 is included under the DTI structure 408 between subregions 404 of a pixel sensor 402 to enable photocurrents generated by the photodiodes 412 of the subregions 404 to be mixed and/or combined into a unified photocurrent that may be used for QPD-based autofocus operations for an image sensor device that includes the pixel sensor array 400.

The DTI structure 408 may include one or more layers. The one or more layers may include an oxide layer 418 and a high dielectric constant (high-k) dielectric liner 420, among other examples. A portion of the oxide layer 418 may extend along the top of the backside surface of the substrate 410 as a buffer layer 422. The oxide layer 418 may function to reflect incident light toward the photodiodes 412 to increase the quantum efficiency of the pixel sensor 402 and to reduce optical crosstalk between the pixel sensor 402 and one or more adjacent pixel sensors 402. In some implementations, the oxide layer 418 includes an oxide material such as a silicon oxide (SiOₓ). In some implementations, a silicon nitride (SiₓN_{y}), a silicon carbide (SiCₓ), or a mixture thereof, such as a silicon carbon nitride (SiCN), a silicon oxynitride (SiON), or another type of dielectric material is used in place of the oxide layer 418. The high-k dielectric liner 420 may include a silicon nitride (SiₓN_{y}), a silicon carbide (SiCₓ), an aluminum oxide (AlₓO_{y} such as Al₂O₃), a tantalum oxide (TaₓO_{y} such as Ta₂O₅), a hafnium oxide (HfOₓ such as HfO₂) and/or another high-k dielectric material.

As further shown in FIG. 4E, drain gates 108 of the ToF sensor circuits 100 associated with the pixel sensor 402 may be located under the DTI structure 408. In other cross-sectional views of the pixel sensor 402, (e.g., cross-sectional views along a perimeter of the pixel sensor 402), control gates 104, control gates 106, floating diffusion regions 114, floating diffusion regions 116, and/or drain regions 118 may be located under the DTI structure 408. The control gates 104 and 106, and the drain gates 108, may be located in a dielectric layer below the frontside surface of the substrate 410. The floating diffusion regions 114, the floating diffusion regions 116, and/or the drain regions 118 may be located in the substrate 410 under the DTI structure 408. The floating diffusion regions 114, the floating diffusion regions 116, and/or the drain regions 118 may include doped portions of the substrate 410 under the DTI structure 408.

A grid structure 424 may be included over and/or on the buffer layer 422 above the backside surface of the substrate 410. The grid structure 424 may include a plurality of interconnected structures formed from one or more layers that are etched to form the interconnected structures. In a top view of the grid structure 424, the grid structure 424 has a grid-shaped configuration similar to the DTI structure 408. In particular, the grid structure 424 may be over the DTI structure 408 and conform to the shape and/or arrangement of the DTI structure 408, except that the grid structure 424 may be omitted from between the subregions 404 of the pixel sensor 402 and may instead be included only around the perimeter of the pixel sensor 402. The grid structure 424 may be configured to provide increased optical crosstalk reduction for the pixel sensors 402 in the pixel sensor array 400, in combination with the DTI structure 408.

The grid structure 424 may include an oxide grid, a dielectric grid, a color filter in a box (CIAB) grid, and/or a composite metal grid (CMG), among other examples. In some implementations, the grid structure 424 includes a metal layer and a dielectric layer over and/or on the metal layer. The metal layer may include tungsten (W), cobalt (Co), and/or another type of metal or metal-containing material. The dielectric layer may include an organic material, an oxide, a nitride, and/or another type of dielectric material such as a silicon oxide (SiOₓ) (e.g., silicon dioxide (SiO₂)), a hafnium oxide (HfOₓ), a hafnium silicon oxide (HfSiOₓ), an aluminum oxide (AlₓO_{y}), a silicon nitride (SiₓN_{y}), a zirconium oxide (ZrOₓ), a magnesium oxide (MgOₓ), a yttrium oxide (YₓO_{y}), a tantalum oxide (TaₓO_{y}), a titanium oxide (TiOₓ), a lanthanum oxide (LaₓO_{y}), a barium oxide (BaOₓ), a silicon carbide (SiC), a lanthanum aluminum oxide (LaAlOx), a strontium oxide (SrO), a zirconium silicon oxide (ZrSiOₓ), and/or a calcium oxide (CaO), among other examples.

A color filter region 426 may be included in the areas between the columns of the grid structure 424. For example, the color filter region 426 may be formed in between columns of the grid structure 424 over the photodiodes 412 of the pixel sensor 402. In this way, a single color filter region 426 is included over the photodiodes 412 of the subregions 404 of the pixel sensor 402, as opposed to having individual color filter regions 426 over each of the subregions 404. Each pixel sensor 402 in the pixel sensor array 400 may include a single color filter region 426. A refractive index of the color filter region 426 may be greater relative to a refractive index of the grid structure 424 to increase a likelihood of a total internal reflection in the color filter regions 426 at an interface between the sidewalls of the color filter regions 426 and the sidewalls of the grid structure 424, which may increase the quantum efficiency of the pixel sensors 402.

The color filter region 426 may be configured to filter incident light to allow a particular wavelength of the incident light to pass to the photodiodes 412 of the pixel sensor 402. For example, the color filter region 426 may filter red light for the pixel sensor 402. As another example, the color filter region 426 may filter green light for the pixel sensor 402. As another example, the color filter region 426 may filter blue light for the pixel sensor 402.

A blue filter region may permit the component of incident light near a 450 nanometer wavelength to pass through a color filter region 426 and block other wavelengths from passing. A green filter region may permit the component of incident light near a 550 nanometer wavelength to pass through a color filter region 426 and block other wavelengths from passing. A red filter region may permit the component of incident light near a 650 nanometer wavelength to pass through a color filter region 426 and block other wavelengths from passing. A yellow filter region may permit the component of incident light near a 580 nanometer wavelength to pass through a color filter region 426 and block other wavelengths from passing.

In some implementations, a color filter region 426 may be non-discriminating or non-filtering, which may define a white pixel sensor. A non-discriminating or non-filtering color filter region 426 may include a material that permits all wavelengths of light to pass into the associated photodiodes 412. In some implementations, a color filter region 426 may be an NIR bandpass color filter region, which may define an NIR pixel sensor. An NIR bandpass color filter region 426 may include a material that permits the portion of incident light in an NIR wavelength range to pass to the associated photodiodes 412 while blocking visible light from passing.

An under layer 428 may be included over and/or on the color filter region 426. The under layer 428 may include an approximately flat layer that provides an approximately flat dielectric substrate on which a micro lens 406 may be formed. The micro lens 406 may be included over the color filter region 426 of the pixel sensor 402. In this way, a single micro lens 406 is included over the single color filter region 426, and over the photodiodes 412, of the pixel sensor 402 (e.g., as opposed to individual micro lenses for each of the photodiodes 412 of the pixel sensor 402). The micro lens 406 may be formed to focus incident light 430 toward the photodiodes 412 of the subregions 404 of the pixel sensor 402.

As further shown in FIG. 4E, a back end of line (BEOL) region 432 may be included on the frontside of the substrate 410. The BEOL region 432 may include one or more dielectric layers 434 and one or more metallization layers 436 included in the one or more dielectric layers 434 that electrically connect portions of the pixel sensor array 400. The one or more dielectric layers 434 may include a silicon oxide (SiOₓ), a silicon nitride (SiₓN_{y}), a silicon carbide (SiCₓ), or a mixture thereof, such as a silicon carbon nitride (SiCN), or a silicon oxynitride (SiON), among other examples. The one or more metallization layers 436 may include trenches, vias, interconnects, columns, pillars, single damascene structures, and/or dual damascene structures, among other examples. The one or more metallization layers 436 may include tungsten (W), cobalt (Co), titanium (Ti), copper (Cu), gold (Au), silver (Ag), molybdenum (Mo), ruthenium (Ru), a metal alloy, and/or another type of electrically conductive material, among other examples. The control gates 104, the control gates 106, the drain gates 108, the floating diffusion regions 114, the floating diffusion regions 116, and/or drain regions 118 may be electrically connected with the one or more metallization layers 436 through interconnects 438. The interconnects 438 may include tungsten (W), cobalt (Co), titanium (Ti), copper (Cu), gold (Au), silver (Ag), molybdenum (Mo), ruthenium (Ru), a metal alloy, and/or another type of electrically conductive material, among other examples.

FIG. 4F illustrates another cross-section view, along the line C-C illustrated in FIGS. 4B, 4C, and 4D, of an example pixel sensor 402 in the 4-cell QPD region of the pixel sensor array 400 illustrated in FIG. 4B. FIG. 4F illustrates an alternative implementation, corresponding to the top-down view of the pixel sensor array 400 in FIG. 4B, in which the micro lenses 406 are offset (or off-centered) relative to the other structures of the pixel sensors 402. In addition, the grid structure 424, the color filter regions 426, and/or the under layer 428 may also be offset (or off-centered) relative to the other structures of the pixel sensors 402.

As indicated above, FIGS. 4A-4F are provided as examples. Other examples may differ from what is described with regard to FIGS. 4A-4F.

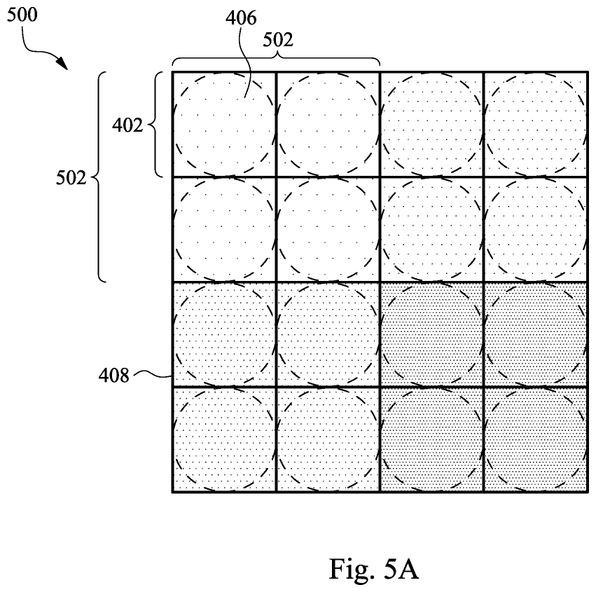

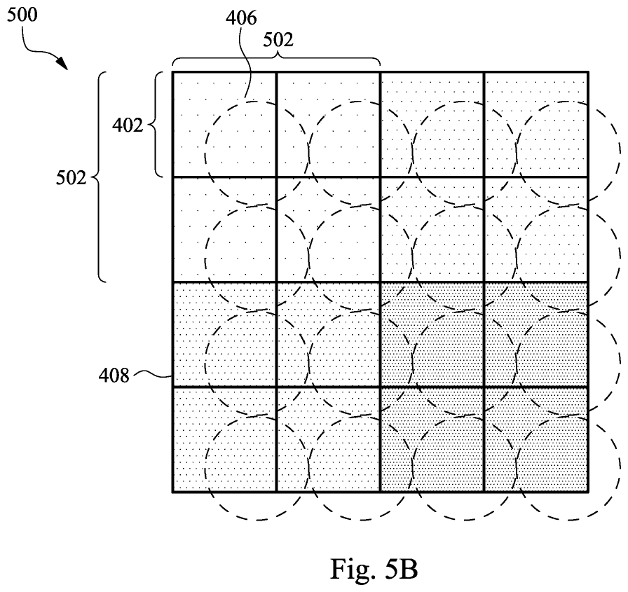

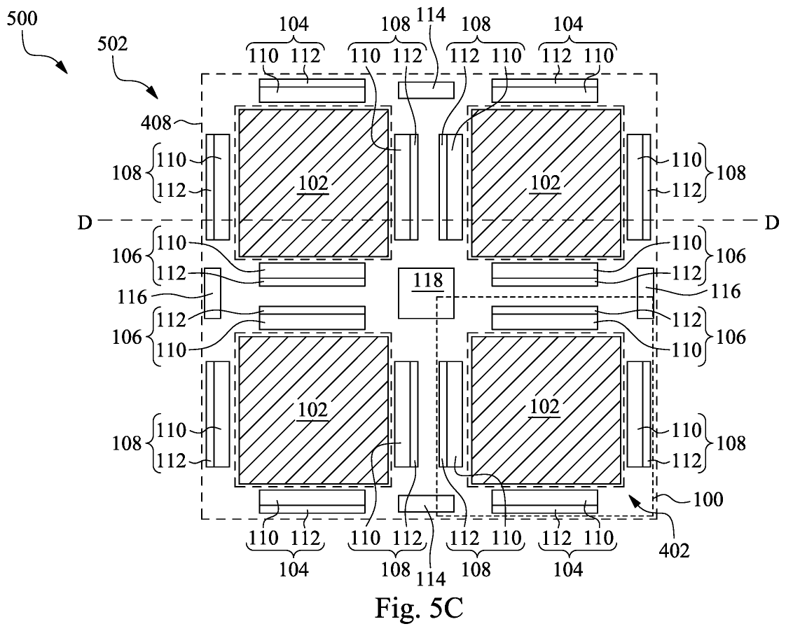

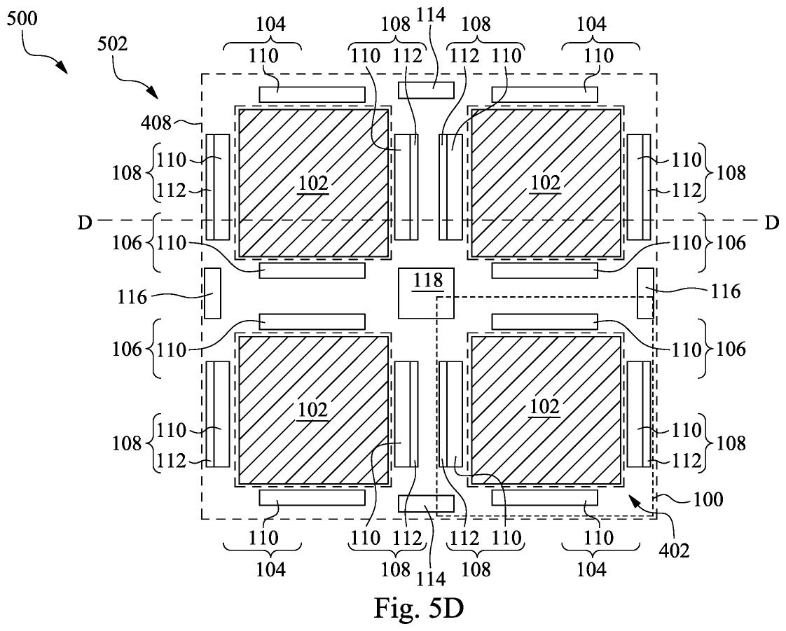

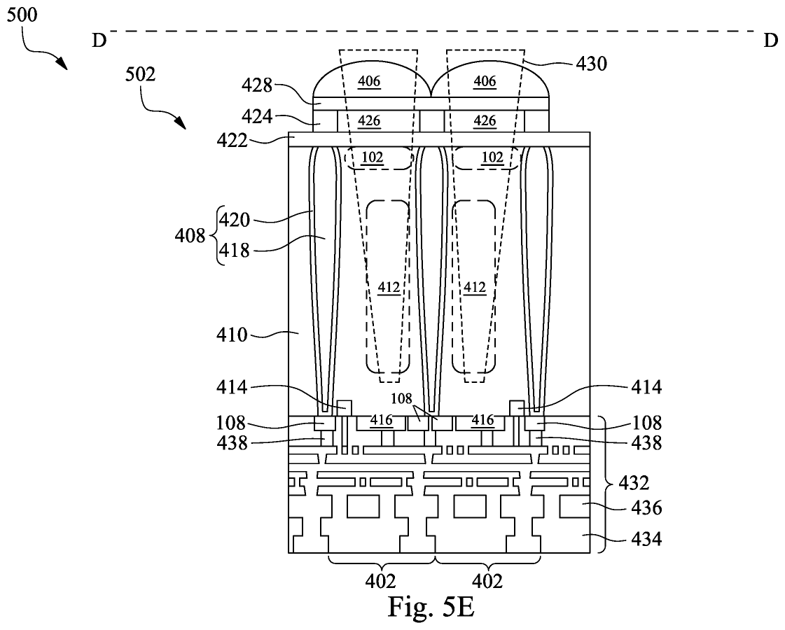

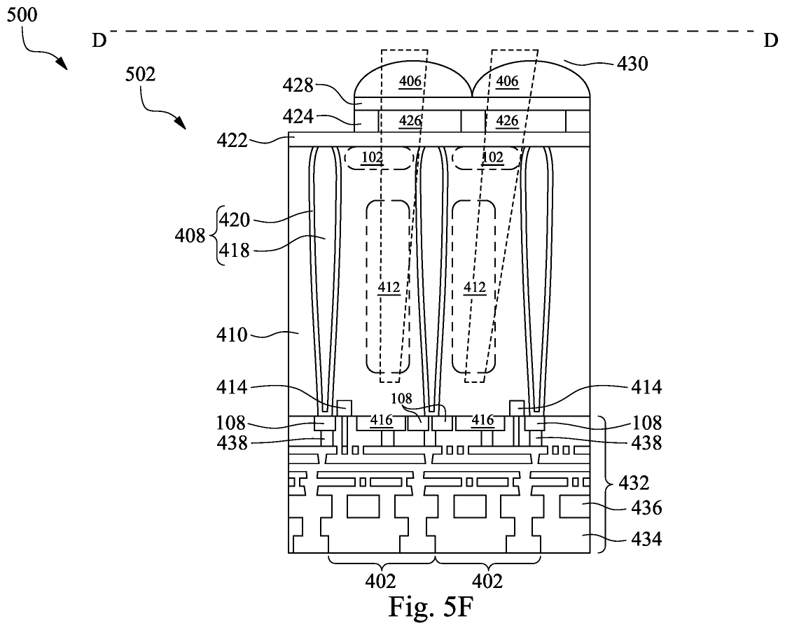

FIGS. 5A-5F are diagrams of example implementations of a pixel sensor array 500 described herein. The pixel sensor array 500 may be included on a sensor die of an image sensor device, such as a CIS device or a time-resolved CIS device.

As shown in FIGS. 5A-5F, the example implementations of the pixel sensor array 500 may include a similar combination and/or arrangement of layers and/or structures as the example implementations of the pixel sensor array 400 illustrated and described in connection with FIGS. 4A-4F. For example, the example implementations of the pixel sensor array 500 may include elements 402-438. However, and as shown in FIGS. 5A and 5B, the example implementations of the pixel sensor array 500 may include 4-cell (4C) pixel sensors 502 that each include 4 pixel sensors 402 arranged in a grid, where each pixel sensor 402 of a 4C pixel sensor 502 includes a respective micro lens 406. Each of the pixel sensors 402 of a 4C pixel sensor 502 may be configured to absorb photons of light in the same particular wavelength range of incident light 430.

As shown in top-down views in FIGS. 5C and 5D, the pixel sensor array 500 may include one or more ToF sensor circuits 100 that are configured to generate distance information associated with incident light (e.g., a sensing current indicating a roundtrip distance of travel of the incident light). The combination of the color information generated by the 4C pixel sensors 502 and the distance information generated by the ToF sensor circuit(s) 100 may be used to generate a 3D ToF color image. In some implementations, a plurality of ToF sensor circuits 100 may be included under the DTI structure 408 and around the perimeter of a 4C pixel sensor 502. For example, a ToF sensor circuit 100 may be included around each pixel sensor 402 of the 4C pixel sensor 502. This enables the ToF sensor circuits 100 to generate distance information for each of the pixel sensors 402 of the 4C pixel sensor 502.

As shown in FIGS. 5C and 5D, the control gates 104 and 106 of a ToF sensor circuit 100 may be located on opposing sides of a pixel sensor 402 of the 4C pixel sensor 502. The aperture 102 of the ToF sensor circuit 100 may correspond to an opening through the DTI structure 408. The drain gates 108 of the ToF sensor circuit 100 may be located on opposing sides of the pixel sensor 402 of the 4C pixel sensor 502 such that the control gate 104 and the drain gates 108 are on adjacent sides of the pixel sensor 402 of the 4C pixel sensor 502, and the control gate 106 and the drain gates 108 are on adjacent sides of the pixel sensor 402 of the 4C pixel sensor 502. In the example implementation in FIG. 5C, the control gates 104 and 106, and the drain gates 108, of the ToF sensor circuits 100 include both a p-type portion 110 and an n-type portion 112. In the example implementation in FIG. 5D, the n-type portions 112 are omitted from the control gates 104 and 106, and included only in the drain gates 108.

As further shown in FIGS. 5C and 5D, floating diffusion regions 114 and 116 of the ToF sensor circuits 100 surrounding the pixel sensor 402 of the 4C pixel sensor 502 may be shared by two or more ToF sensor circuits 100. For example, floating diffusion regions 114 may be shared and included in ToF sensor circuits 100 surrounding adjacent pixel sensors 402 of the 4C pixel sensor 502. As another example, floating diffusion regions 116 may be shared and included in ToF sensor circuits 100 surrounding adjacent pixel sensors 402 of the 4C pixel sensor 502. In some implementations, a pixel sensor 402 of the 4C pixel sensor 502 may share a floating diffusion region 114 with a first adjacent pixel sensor 402, and may share a floating diffusion region 116 with a second adjacent pixel sensor 402 different from the first adjacent pixel sensor 402.

A floating diffusion region 114 of a ToF sensor circuit 100 may be located at a first corner of a pixel sensor 402 of the 4C pixel sensor 502 between a control gate 104 and a drain gate 108, and a floating diffusion region 116 of the ToF sensor circuit 100 may be located at a second corner of the pixel sensor 402 opposing the first corner and between a control gate 106 and another drain gate 108. The floating diffusion regions 114 of the ToF sensor circuits 100 surrounding the 4C pixel sensor 502 may be located on opposing sides of the 4C pixel sensor 502. A floating diffusion region 114 may be located between control gates 104 of adjacent ToF sensor circuits 100 surrounding the pixel sensors 402 of the 4C pixel sensor 502, and may be located next to ends of drain gates 108 of the adjacent ToF sensor circuits 100. The floating diffusion regions 116 of the ToF sensor circuits 100 surrounding the pixel sensors 402 of the 4C pixel sensor 502 may be located on opposing sides of the 4C pixel sensor 502. A floating diffusion region 116 may be located between drain gates 108 of adjacent ToF sensor circuits 100 surrounding the pixel sensors 402 of the 4C pixel sensor 502, and may be located next to ends of control gates 106 of the adjacent ToF sensor circuits 100. A floating diffusion region 114 and a floating diffusion region 116 may be located on adjacent sides of the 4C pixel sensor 502.

As further shown in FIGS. 5C and 5D, the ToF sensor circuits 100 surrounding the pixel sensors 402 of the 4C pixel sensor 502 may all share the same drain region 118. Thus, a single drain region 118 may be associated with the 4C pixel sensor 502. The drain region 118 may be located at a cross-road region of the 4C pixel sensor 502 where four corners of the pixel sensors 402 meet. The drain region 118 may be located next to ends of the control gates 106 of the ToF sensor circuits 100, and next to ends of a subset of the drain gates 108 of the ToF sensor circuits 100.

As shown in FIGS. 5E and 5F, the pixel sensors 402 of the 4C pixel sensor 502 may be included in the substrate 410 of the pixel sensor array 500. Each of the pixel sensors 402 of the 4C pixel sensor 502 may include respective sets of a photodiode 412, a drain region 414, a transfer gate 416, a color filter region 426, and a micro lens 406. The DTI structure 408 may surround each of the pixel sensors 402 of the 4C pixel sensor 502. The grid structure 424 may be over the DTI structure 408 and conform to the shape and/or arrangement of the DTI structure 408 such that the grid structure 424 surrounds each of the pixel sensors 402 of the 4C pixel sensor 502.

As further shown in FIGS. 5E and 5F, drain gates 108 of the ToF sensor circuits 100 associated with the 4C pixel sensor 502 may be located under the DTI structure 408. In other cross-sectional views of the 4C pixel sensor 502, (e.g., cross-sectional views along a perimeter of the 4C pixel sensor 502), control gates 104, control gates 106, floating diffusion regions 114, floating diffusion regions 116, and/or drain regions 118 may be located under the DTI structure 408. The control gates 104 and 106, and the drain gates 108, may be located in a dielectric layer below the frontside surface of the substrate 410. The floating diffusion regions 114, the floating diffusion regions 116, and/or the drain regions 118 may be located in the substrate 410 under the DTI structure 408. The floating diffusion regions 114, the floating diffusion regions 116, and/or the drain regions 118 may include doped portions of the substrate 410 under the DTI structure 408.

As indicated above, FIGS. 5A-5F are provided as examples. Other examples may differ from what is described with regard to FIGS. 5A-5F.

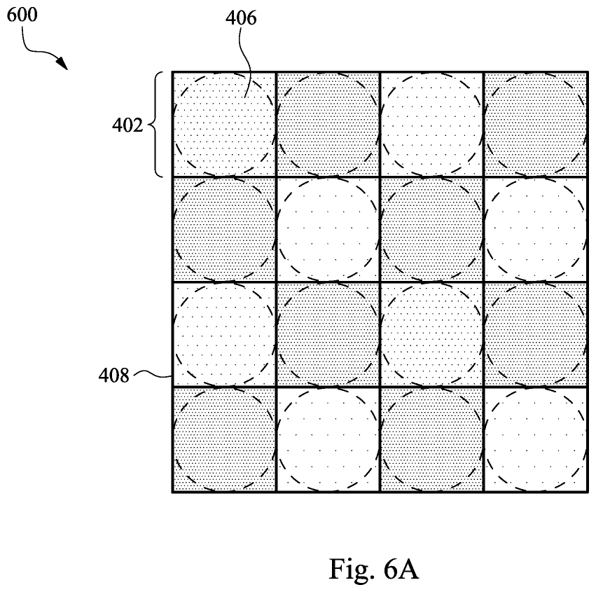

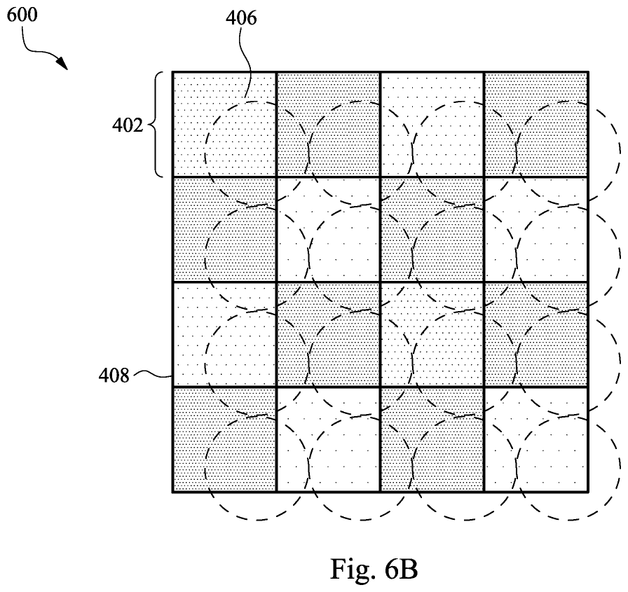

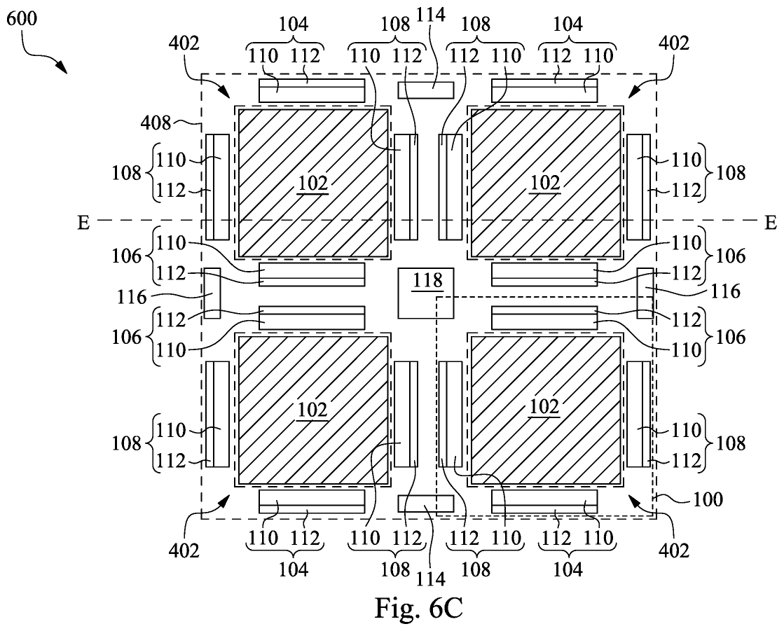

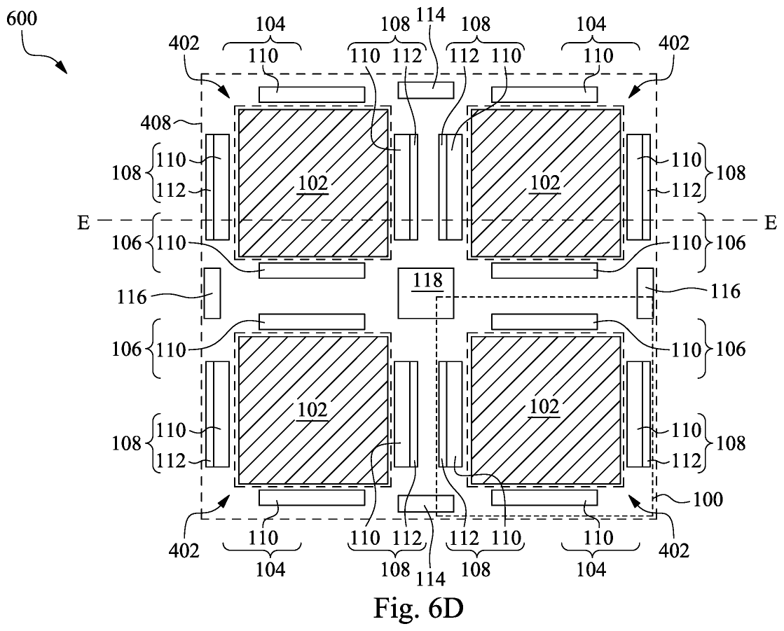

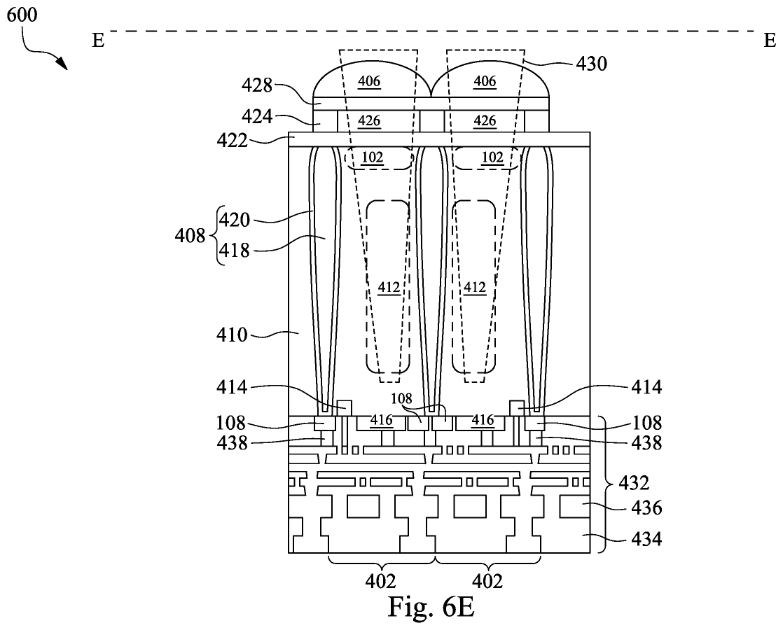

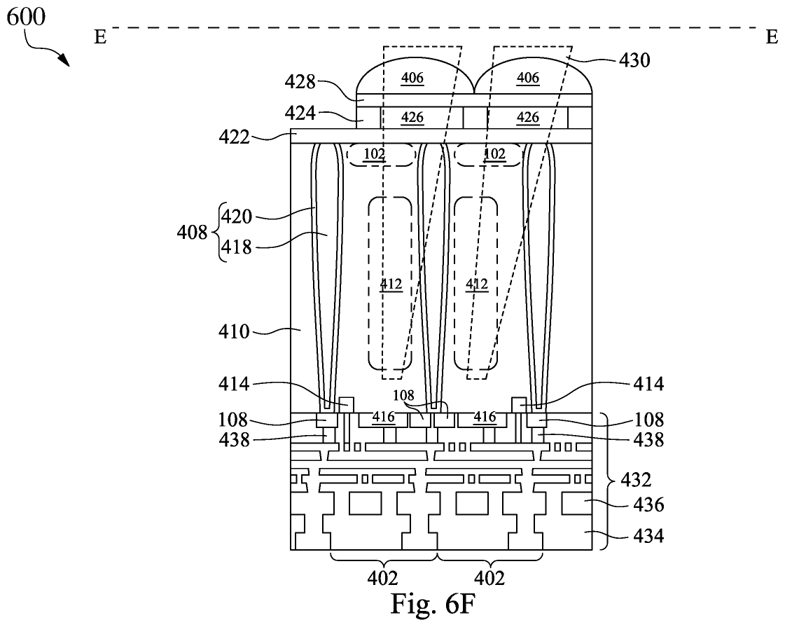

FIGS. 6A-6F are diagrams of example implementations of a pixel sensor array 600 described herein. The pixel sensor array 600 may be included on a sensor die of an image sensor device, such as a CIS device or a time-resolved CIS device.

As shown in FIGS. 6A-6F, the example implementations of the pixel sensor array 600 may include a similar combination and/or arrangement of layers and/or structures as the example implementations of the pixel sensor array 400 illustrated and described in connection with FIGS. 4A-4F. For example, the example implementations of the pixel sensor array 600 may include elements 402-438. However, and as shown in FIGS. 6A and 6B, the example implementations of the pixel sensor array 600 may include 1-cell (1C) pixel sensors 402 that are distributed throughout the pixel sensor array 600.

As shown in top-down views in FIGS. 6C and 6D, the pixel sensor array 600 may include one or more ToF sensor circuits 100 that are configured to generate distance information associated with incident light (e.g., a sensing current indicating a roundtrip distance of travel of the incident light). The combination of the color information generated by the pixel sensors 402 and the distance information generated by the ToF sensor circuit(s) 100 may be used to generate a 3D ToF color image. In some implementations, a ToF sensor circuit 100 may be included under the DTI structure 408 and around the perimeter of one or more of the pixel sensors 402. This enables the ToF sensor circuits 100 to generate distance information for each of the one or more pixel sensors 402.

As shown in FIGS. 6C and 6D, the control gates 104 and 106 of a ToF sensor circuit 100 may be located on opposing sides of a pixel sensor 402. The aperture 102 of the ToF sensor circuit 100 may correspond to an opening through the DTI structure 408. The drain gates 108 of the ToF sensor circuit 100 may be located on opposing sides of the pixel sensor 402 such that the control gate 104 and the drain gates 108 are on adjacent sides of the pixel sensor 402, and the control gate 106 and the drain gates 108 are on adjacent sides of the pixel sensor 402. In the example implementation in FIG. 6C, the control gates 104 and 106, and the drain gates 108, of the ToF sensor circuits 100 include both a p-type portion 110 and an n-type portion 112. In the example implementation in FIG. 6D, the n-type portions 112 are omitted from the control gates 104 and 106, and included only in the drain gates 108.

As further shown in FIGS. 6C and 6D, floating diffusion regions 114 and 116 of the ToF sensor circuits 100 surrounding the pixel sensors 402 may be shared by two or more ToF sensor circuits 100. For example, floating diffusion regions 114 may be shared and included in ToF sensor circuits 100 surrounding adjacent pixel sensors 402. As another example, floating diffusion regions 116 may be shared and included in ToF sensor circuits 100 surrounding adjacent pixel sensors 402. In some implementations, a pixel sensor 402 may share a floating diffusion region 114 with a first adjacent pixel sensor 402, and may share a floating diffusion region 116 with a second adjacent pixel sensor 402 different from the first adjacent pixel sensor 402.

A floating diffusion region 114 of a ToF sensor circuit 100 may be located at a first corner of a pixel sensor 402 between a control gate 104 and a drain gate 108, and a floating diffusion region 116 of the ToF sensor circuit 100 may be located at a second corner of the pixel sensor 402 opposing the first corner and between a control gate 106 and another drain gate 108. The ToF sensor circuits 100 surrounding a plurality of the pixel sensors 402 may all share the same drain region 118. Thus, a single drain region 118 may be associated with a plurality of ToF sensor circuits 100 and a plurality of pixel sensors 402. The drain region 118 may be located at a cross-road region of the plurality of pixel sensors 402 where four corners of the pixel sensors 402 meet. The drain region 118 may be located next to ends of the control gates 106 of the ToF sensor circuits 100, and next to ends of a subset of the drain gates 108 of the ToF sensor circuits 100.

As shown in FIGS. 6E and 6F, the pixel sensors 402 may be included in the substrate 410 of the pixel sensor array 600. Each of the pixel sensors 402 may include respective sets of a photodiode 412, a drain region 414, a transfer gate 416, a color filter region 426, and a micro lens 406. The DTI structure 408 may surround each of the pixel sensors 402. The grid structure 424 may be over the DTI structure 408 and conform to the shape and/or arrangement of the DTI structure 408 such that the grid structure 424 surrounds each of the pixel sensors 402.

As further shown in FIGS. 6E and 6F, drain gates 108 of the ToF sensor circuits 100 associated with the pixel sensors 402 may be located under the DTI structure 408. In other cross-sectional views of the pixel sensors 402, (e.g., cross-sectional views along a perimeter of the pixel sensor 402), control gates 104, control gates 106, floating diffusion regions 114, floating diffusion regions 116, and/or drain regions 118 may be located under the DTI structure 408. The control gates 104 and 106, and the drain gates 108, may be located in a dielectric layer below the frontside surface of the substrate 410. The floating diffusion regions 114, the floating diffusion regions 116, and/or the drain regions 118 may be located in the substrate 410 under the DTI structure 408. The floating diffusion regions 114, the floating diffusion regions 116, and/or the drain regions 118 may include doped portions of the substrate 410 under the DTI structure 408.

As indicated above, FIGS. 6A-6F are provided as examples. Other examples may differ from what is described with regard to FIGS. 6A-6F.

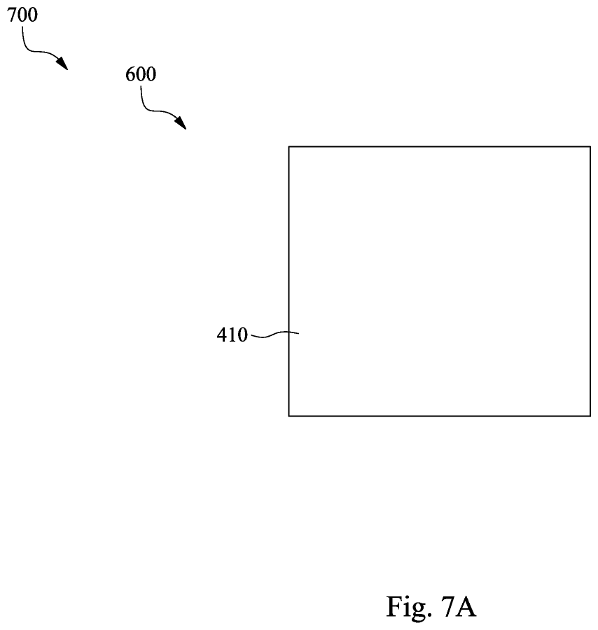

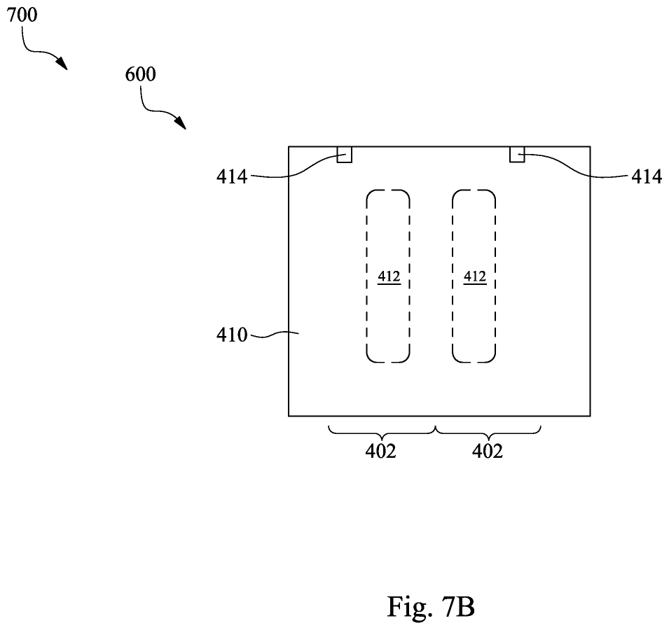

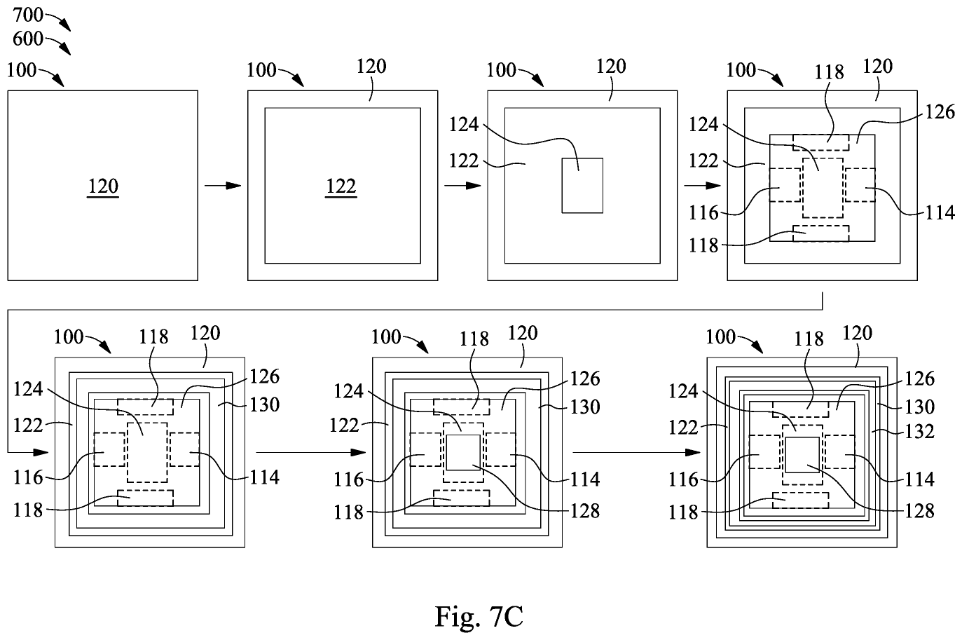

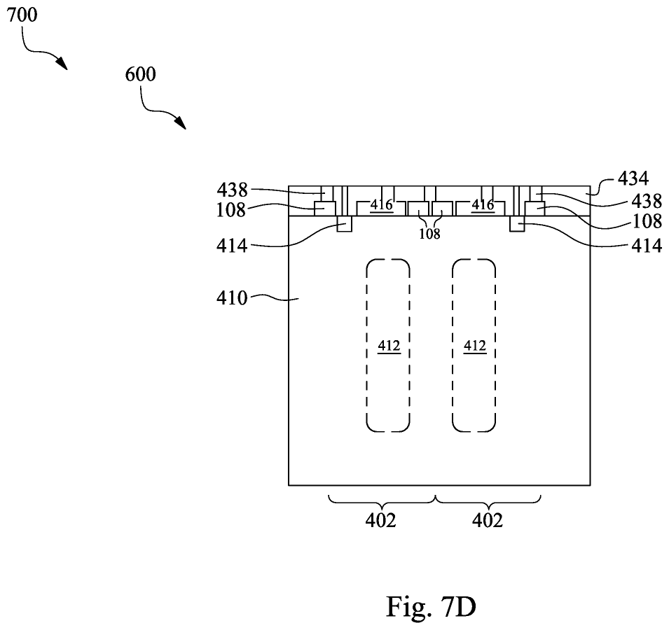

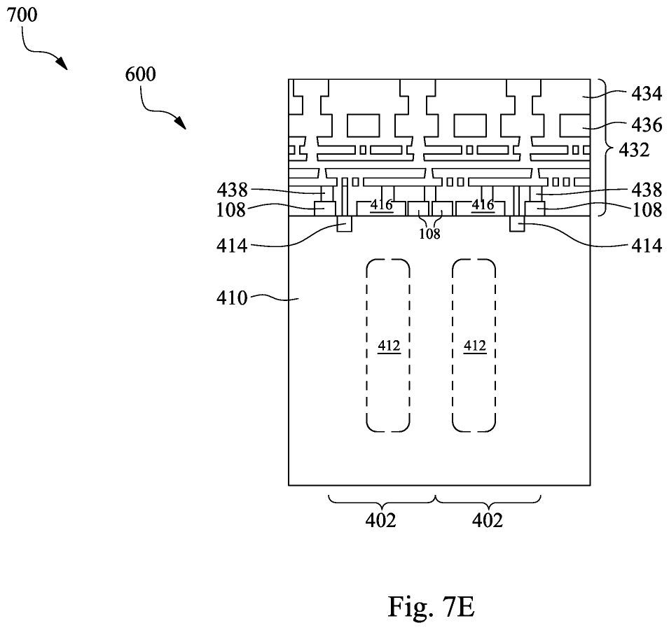

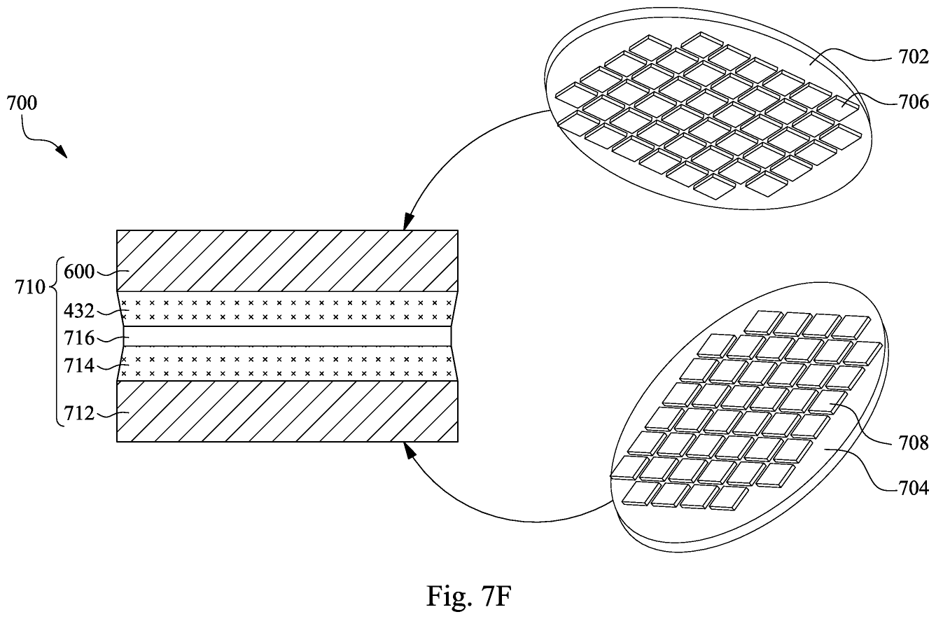

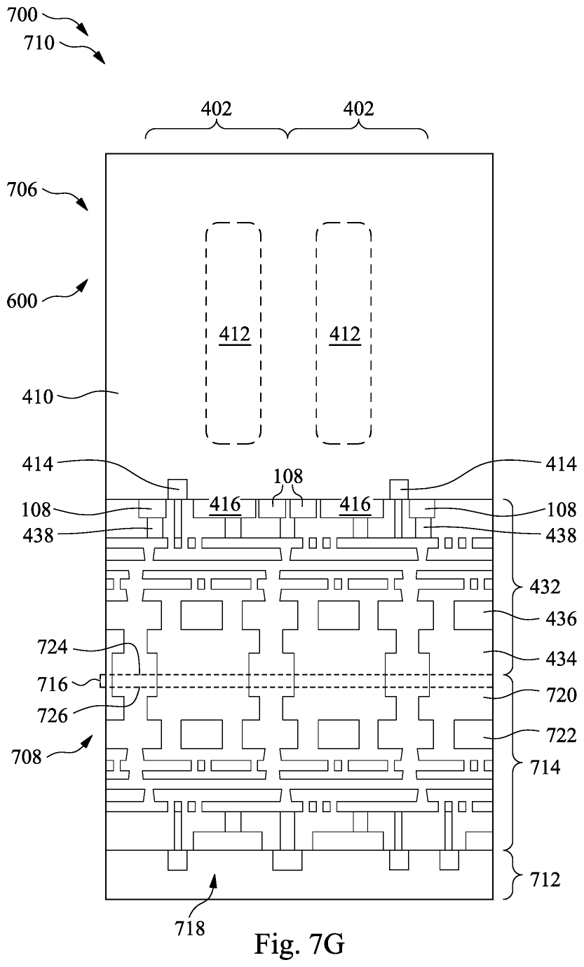

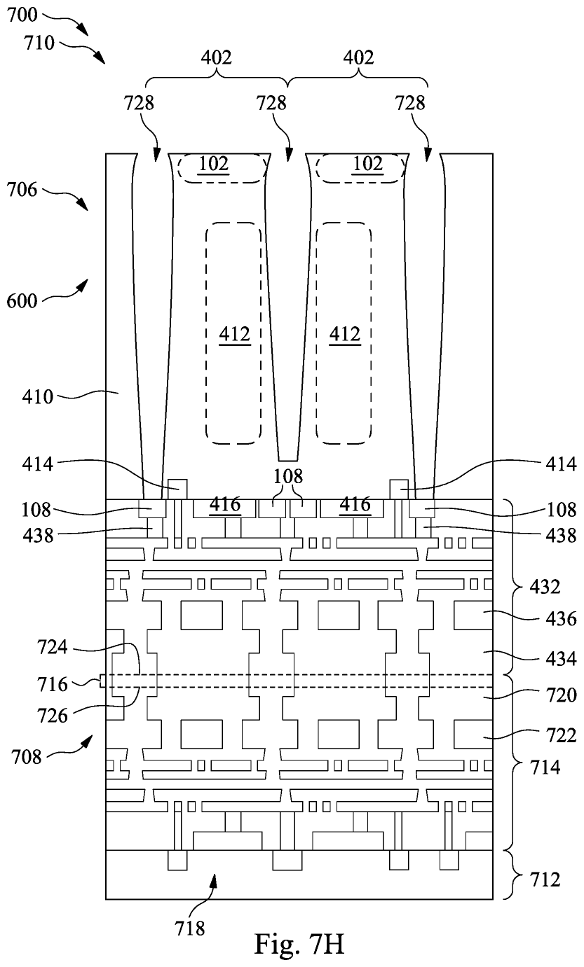

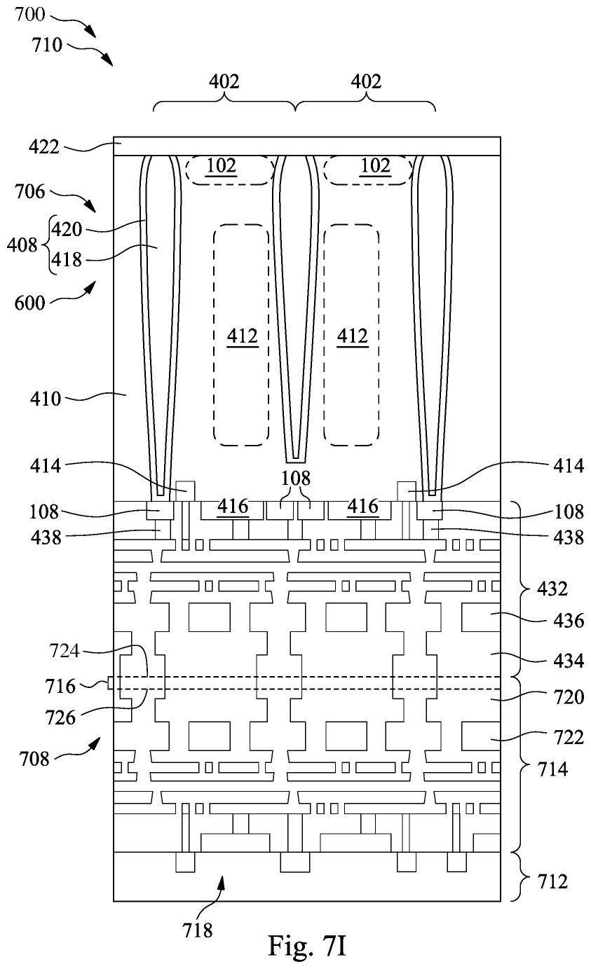

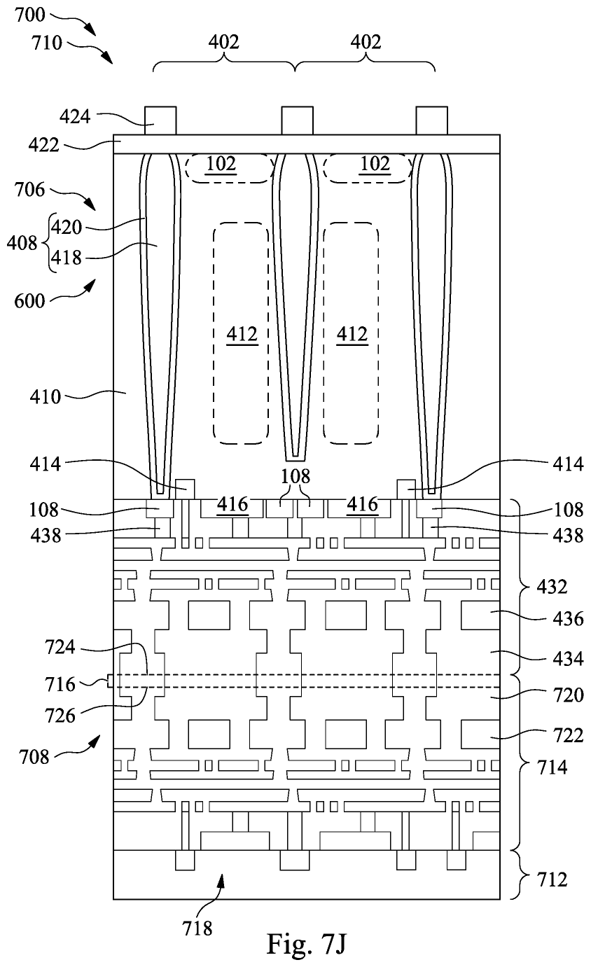

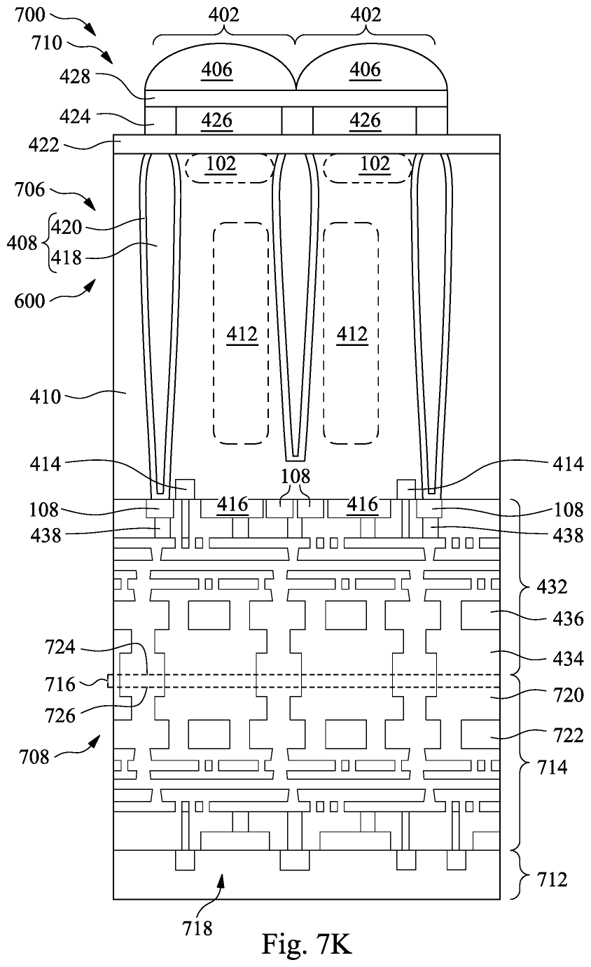

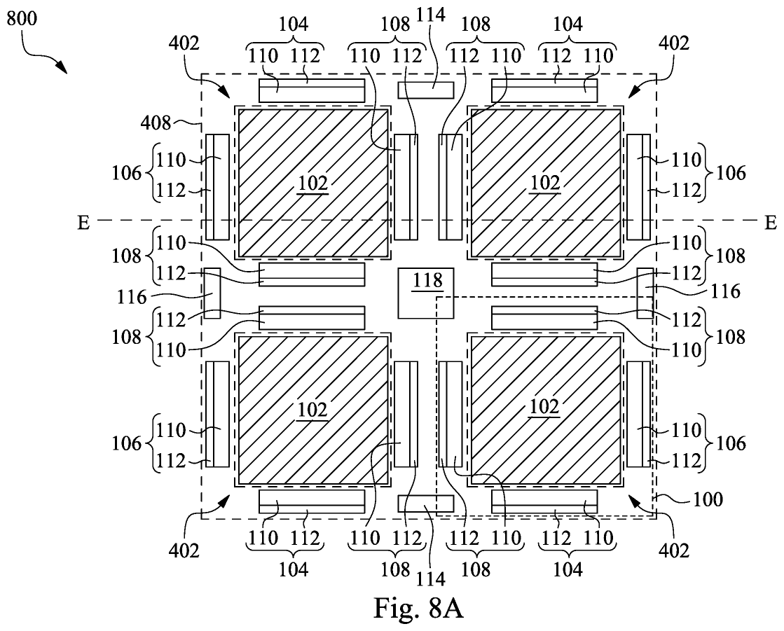

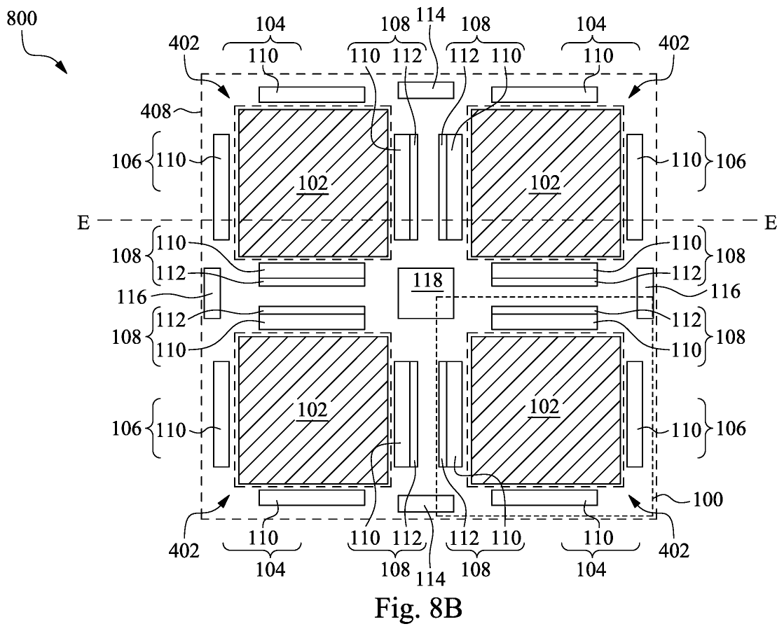

FIGS. 7A-7K are diagrams of an example implementation 700 of forming an image sensor device described herein. While the example implementation 700 includes forming the pixel sensor array 600 in the image sensor device, the semiconductor processing techniques may be used to form one or more implementations of the pixel sensor array 400, one or more implementations of the pixel sensor array 500, and/or one or more implementations of a pixel sensor array 800 (described in connection with FIGS. 8A and/or 8B) in the image sensor device. In some implementations, one or more of the semiconductor processing operations described in connection with FIGS. 7A-7K may be performed using one or more semiconductor processing tools, such as a deposition tool, an exposure tool, a developer tool, an etch tool, a planarization tool, a plating tool, an ion implantation tool, and/or a bonding tool, among other examples.

Turning to FIG. 7A, one or more of the semiconductor processing operations in the example implementation 700 may be performed in connection with the substrate 410. The substrate 410 may be provided as a semiconductor wafer or another type of semiconductor work piece.

As shown in FIG. 7B, a plurality of regions of the substrate 410 may be doped to form photodiodes 412 for one or more pixel sensors 402. An ion implantation tool may be used to dope the substrate 410 to form one or more n-type regions and/or one or more p-type regions of the photodiodes 412. The ion implantation tool may be used to implant p+ ions in the substrate 410 to form the p-type region(s) and/or may implant n+ ions in the substrate 410 to form the n-type region(s).

As further shown in FIG. 7B, one or more regions of the substrate 410 may be doped to form the drain regions 414 of the one or more pixel sensors 402. In some implementations, an ion implantation tool may be used to dope by implanting n+ ions in the substrate 410 to form the drain regions 414.

As shown in FIG. 7C, one or more ToF sensor circuits 100 may be formed. The substrate 120 of the ToF sensor circuit 100 may a part of or may be included in the substrate 410. One or more portions of the substrate 120 may be doped (e.g., using an ion implantation tool) to form the deep well 122 (which, in some implementations, may be omitted). One or more portions of the substrate 120 may be doped to form the doped region 124 in the deep well 122. One or more portions of the substrate 120 may be doped to form the doped well 126 over the doped region 124 and in the deep well 122. The doped well 126 may include the floating diffusion regions 114 and 116, and the drain regions 118. One or more portions of the substrate 120 may be doped to form the doped guard ring 130 in the deep well 122 and around the doped region 124 and the doped well 126. One or more portions of the substrate 120 may be doped to form the doped region 128 over the doped region 124 and the doped well 126. One or more portions of the substrate 120 may be doped to form the doped region 132 over the doped guard ring 130.

As shown in FIG. 7D, transfer gates 416 may be formed over the front side surface of the substrate 410. Moreover, drain gates 108, control gates 106 (not shown), and control gates 104 (not shown), are formed over the front side surface of the substrate 410. In some implementations, a gate dielectric layer may be formed on the front side surface of the substrate 410, and the control gates 104 and 106, the drain gates 108, and the transfer gates 416 may be formed over and/or on the gate dielectric layer. In some implementations, a deposition tool is used to deposit the control gates 104 and 106, the drain gates 108, and the transfer gates 416. In some implementations, the control gates 104 and 106, the drain gates 108, and/or the transfer gates 416 may include polysilicon that is doped with one or more types of dopants to form p-type portions 110 and n-type portions 112, or just the p-type portions 110 without the n-type portions (e.g., for the control gates 104 and 106, in some implementations). In some implementations, the control gates 104 and 106, the drain gates 108, and/or the transfer gates 416 may include high-k dielectric and metal materials (e.g., metal gates or MGs).

As further shown in FIG. 7D, one or more dielectric layers 434 may be formed on the front side of the substrate 410. A deposition tool may be used to deposit the one or more dielectric layers 434 in a physical vapor deposition (PVD) operation, an atomic layer deposition (ALD) operation, a chemical vapor deposition (CVD) operation, an oxidation operation, or another type of deposition operation. In some implementations, a planarization tool may be used to planarize the one or more dielectric layers 434 after the one or more dielectric layers 434 are deposited. The one or more dielectric layers 434 may be formed over the control gates 104 and 106, the drain gates 108, and/or the transfer gates 416.

As further shown in FIG. 7D, interconnects 438 may be formed in the one or more dielectric layers 434. Interconnects 438 may be formed to be electrically coupled and/or physically coupled with the control gates 104 and 106, the drain gates 108, the floating diffusion regions 114 and 116 (not shown), the drain regions 118 (not shown), the drain regions 414, and/or the transfer gates 416. A deposition tool, an exposure tool, and/or a developer tool may be used to pattern a masking layer, and an etch tool may be used to form recesses or openings in the one or more dielectric layers 434 based on the pattern. One or more deposition tools may be used to deposit the interconnects 438 in the recesses or openings to electrically couple and/or physically couple the control gates 104 and 106, the drain gates 108, the floating diffusion regions 114 and 116 (not shown), the drain regions 118 (not shown), the drain regions 414, and/or the transfer gates 416 with the interconnects 438.

As shown in FIG. 7E, the BEOL region 432 may be formed above the front side surface of the substrate 410. The metallization layers 436 may be electrically coupled and/or physically coupled with the interconnects 438. A deposition tool may be used to deposit one or more dielectric layers 434 in a PVD operation, an ALD operation, a CVD operation, an oxidation operation, or another type of deposition operation. In some implementations, a planarization tool may be used to planarize the one or more dielectric layers 434 after the one or more dielectric layers 434 are deposited. In some implementations, the BEOL region 432 may be formed in a plurality of layers. For example, a first dielectric layer 434 may be deposited, and a first metallization layer 436 (an M1 metallization layer) may be formed in the first dielectric layer 434; a second dielectric layer 434 may be deposited, and a second metallization layer 436 (an M2 metallization layer) may be formed in the second dielectric layer 434; and so on.

As shown in FIG. 7F, the pixel sensor array 600 may be formed on a first wafer 702 that is bonded to a second wafer 704 using a bonding tool. A plurality of image sensor dies 706 (e.g., system on chip (SoC) dies) may be formed on the first wafer 702, and the pixel sensor array 600 may be included on an image sensor die 706 that is bonded with a circuitry die 708 (e.g., an application specific integrated circuit (ASIC) die) from the second wafer 704 to form an image sensor device 710. The circuitry die 708 may include a device region 712 that includes the associated control circuitry for the pixel sensor array 600, and a BEOL region 714. The image sensor die 706 (including the pixel sensor array 600) and the circuitry die 708 may be bonded at a bonding interface 716 between the BEOL regions 432 and 714.

As shown in FIG. 7G, the circuitry die 708 may include one or more semiconductor devices 718 (e.g., transistors, capacitors, resistors, memory cells) in the device region 712. The BEOL region 714 may be formed above the device region 712. A deposition tool may be used to deposit one or more dielectric layers 720 of the BEOL region 714 in a PVD operation, an ALD operation, a CVD operation, an oxidation operation, or another type of deposition operation. A deposition may be used to deposit one or more metallization layers 722 of the BEOL region 714 in a PVD operation, an ALD operation, a CVD operation, a plating operation (e.g., an electroplating operation), and/or another type of deposition operation. In some implementations, a planarization tool may be used to planarize the one or more dielectric layers 720 after the one or more dielectric layers 720 are deposited. In some implementations, the BEOL region 714 may be formed in a plurality of layers. For example, a first dielectric layer 720 may be deposited, and a first metallization layer 722 (an M1 metallization layer) may be formed in the first dielectric layer 720; a second dielectric layer 720 may be deposited, and a second metallization layer 722 (an M2 metallization layer) may be formed in the second dielectric layer 720; and so on.

As further shown in FIG. 7G, the bonding interface 716 may include a dielectric-to-dielectric bonding interface (where the one or more dielectric layers 434 and the one or more dielectric layers 720 are bonded) and/or a metal-to-metal bonding interface where bonding pads 724 of the image sensor die 706 and bonding pads 726 of the circuitry die 708 are bonded. The bonding pads 724 and 726 may each include tungsten (W), cobalt (Co), titanium (Ti), copper (Cu), gold (Au), silver (Ag), molybdenum (Mo), ruthenium (Ru), a metal alloy, and/or another type of electrically conductive material, among other examples.

As shown in FIG. 7H, recesses 728 may be formed into the substrate 410 from the backside surface of the substrate 410. In some implementations, a pattern in a photoresist layer is used to pattern the recesses 728. The recesses 728 may be formed over the control gates 104 and 106 (not shown), and over the drain gates 108. Moreover, the recesses 728 may be formed over the floating diffusion regions 114 and 116 (not shown), and over the drain regions 118 (not shown).

A deposition tool may be used to form the photoresist layer on the backside surface of the substrate 410. An exposure tool may be used to expose the photoresist layer to a radiation source to pattern the photoresist layer. A developer tool may be used to develop and remove portions of the photoresist layer to expose the pattern. An etch tool may be used to etch the substrate 410 based on the pattern to form the recesses 728. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). Alternatively, the pattern in the photoresist layer may be used to transfer the pattern to a hard mask layer that is used for forming the recesses 728.

As shown in FIG. 7I, a high-k dielectric liner 420 may be formed on sidewalls and on bottom surfaces of the recesses 728. A deposition tool may be used to conformally deposit the high-k dielectric liner 420 in a PVD operation, an ALD operation, a CVD operation, and/or another type of deposition operation. The high-k dielectric liner 420 may further be deposited on the backside surface of the substrate 410. In some implementations, the high-k dielectric liner 420 is subsequently removed from the backside surface of the substrate 410. In some implementations, the high-k dielectric liner 420 remains on the backside surface of the substrate 410 (e.g., as an antireflective coating).

As further shown in FIG. 7I, the recesses 728 may be filled with an oxide layer 418 over the high-k dielectric liner 420 to form the DTI structure 408 in the recesses 728. The DTI structure 408 may extend into the substrate 410 around the pixel sensors 402 of the pixel sensor array 600. As further shown in FIG. 7I, the material of the oxide layer 418 may be deposited over the backside surface of the substrate 410 to form the buffer layer 422. A deposition tool may be used to deposit the oxide layer 418 in the recesses to form the DTI structure 408 in a PVD operation, an ALD operation, a CVD operation, an oxidation operation, and/or another type of deposition operation. A deposition tool may be used to deposit the buffer layer 422 in a PVD operation, an ALD operation, a CVD operation, an oxidation operation, and/or another type of deposition operation. In some implementations, a planarization tool may be used to planarize the buffer layer 422 after the buffer layer 422 is deposited.

As shown in FIG. 7J, the grid structure 424 may be formed over the DTI structure 408. A deposition tool may deposit the layer(s) of the grid structure 424 over and/or on the buffer layer 422 in a PVD operation, an ALD operation, a CVD operation, an oxidation operation, a plating operation, and/or another suitable deposition operation. An etch tool may be used to remove portions of the layer(s) to form the grid structure 424.

As shown in FIG. 7K, the color filter regions 426 may be formed in between the grid structure 424, the under layer 428 may be formed over the color filter regions 426 and over the grid structure 424, and the micro lenses 406 may be formed over and/or on the under layer 428.

As indicated above, FIGS. 7A-7K are provided as examples. Other examples may differ from what is described with regard to FIGS. 7A-7K.

FIGS. 8A and 8B are diagrams of example implementations of a pixel sensor array 800 described herein. The pixel sensor array 800 may be included on a sensor die of an image sensor device, such as a CIS device or a time-resolved CIS device. The pixel sensor array 800 may include an arrangement of pixel sensors 402, such as a 4C QPD arrangement of pixel sensors 402 described herein, a 4C pixel sensor arrangement of pixel sensors 402 described herein, a 1C arrangement of pixel sensors 402 described herein, and/or another arrangement of pixel sensors 402.

As shown in FIGS. 8A and 8B, a floating diffusion region 116 may be located between control gates 106 of adjacent ToF sensor circuits 100 and next to ends of drain gates 108 of the adjacent ToF sensor circuits 100. The drain region 118 shared by the ToF sensor circuits 100 may be located next to ends of all of the drain gates 108 of the ToF sensor circuits 100.

In the example implementation in FIG. 8A, the control gates 104 and 106, and the drain gates 108, of the ToF sensor circuits 100 include both a p-type portion 110 and an n-type portion 112. In the example implementation in FIG. 8B, the n-type portions 112 are omitted from the control gates 104 and 106, and included only in the drain gates 108.

As indicated above, FIGS. 8A and 8B are provided as examples. Other examples may differ from what is described with regard to FIGS. 8A and 8B.

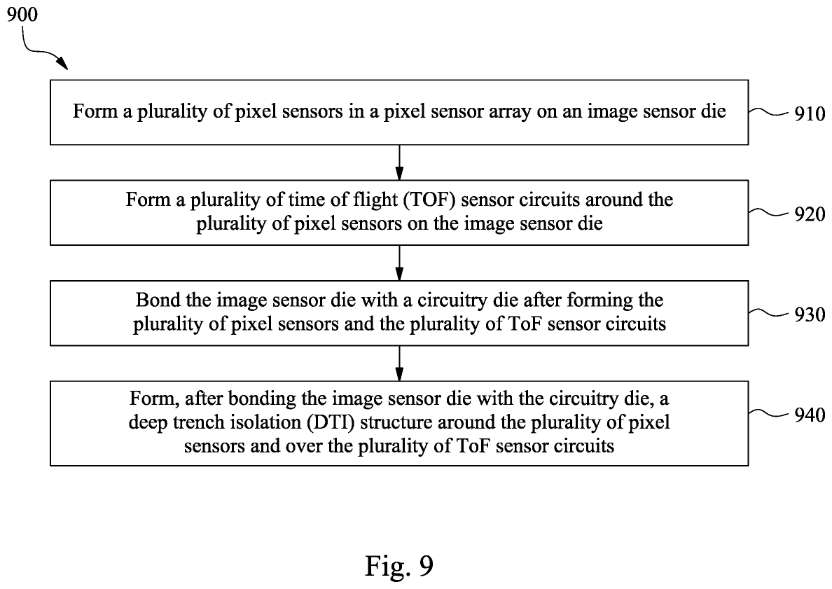

FIG. 9 is a flowchart of an example process 900 associated forming a pixel sensor array described herein. In some implementations, one or more process blocks of FIG. 9 are performed using one or more semiconductor processing tools, such as a deposition tool, an exposure tool, a developer tool, an etch tool, a planarization tool, a plating tool, an ion implantation, and/or a bonding tool, among other examples.

As shown in FIG. 9, process 900 may include forming a plurality of pixel sensors in a pixel sensor array on an image sensor die (block 910). For example, one or more semiconductor processing tools may be used to form a plurality of pixel sensors 402 in a pixel sensor array (e.g., the pixel sensor array 400, the pixel sensor array 500, the pixel sensor array 600) on an image sensor die 706, as described herein.

As further shown in FIG. 9, process 900 may include forming a plurality of ToF sensor circuits around the plurality of pixel sensors on the image sensor die (block 920). For example, one or more semiconductor processing tools may be used to form a plurality of ToF sensor circuits 100 around the plurality of pixel sensors 402 on the image sensor die 706, as described herein.

As further shown in FIG. 9, process 900 may include bonding the image sensor die with a circuitry die after forming the plurality of pixel sensors and the plurality of ToF sensor circuits (block 930). For example, one or more semiconductor processing tools may be used to bond the image sensor die 706 with a circuitry die 708 after forming the plurality of pixel sensors 402 and the plurality of ToF sensor circuits 100, as described herein.

As further shown in FIG. 9, process 900 may include forming, after bonding the image sensor die with the circuitry die, a DTI structure around the plurality of pixel sensors and over the plurality of ToF sensor circuits (block 940). For example, one or more of the semiconductor processing tools may be used to form, after bonding the image sensor die with the circuitry die, a DTI structure 408 around the plurality of pixel sensors 402 and over the plurality of ToF sensor circuits 100, as described herein.

Process 900 may include additional implementations, such as any single implementation or any combination of implementations described below and/or in connection with one or more other processes described elsewhere herein.

In a first implementation, forming a ToF sensor circuit 100 of the plurality of ToF sensor circuits 100 includes forming a first doped region 124 in a substrate (e.g., a substrate 120, a substrate 410) of the image sensor die 706, forming a doped well 126 over the first doped region 124, forming a doped guard ring 130 around the first doped region 124 and the doped well 126, forming a second doped region 128 over the doped well 126, and forming a third doped region 132 over the doped guard ring 130.

In a second implementation, alone or in combination with the first implementation, the first doped region comprises a first p-type doped region, wherein the doped well comprises an n-type doped well, wherein the doped guard ring comprises a p-type doped guard ring, wherein the second doped region comprises an n-type doped region, and wherein the third doped region comprises a second p-type doped region.

In a third implementation, alone or in combination with one or more of the first and second implementations, the first doped region 124 includes a first n-type doped region, the doped well 126 includes a p-type doped well, the doped guard ring includes an n-type doped guard ring, the second doped region 128 includes a p-type doped region, and the third doped region 132 includes a second n-type doped region.

In a fourth implementation, alone or in combination with one or more of the first through third implementations, forming the ToF sensor circuit 100 further includes forming a deep n-type well (e.g., a deep well 122) in the substrate, and the first n-type doped region, the p-type doped well, and the n-type doped guard ring are formed in the deep n-type well.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, a pixel sensor array may include a plurality of pixel sensors configured to generate color information associated with incident light, and a ToF sensor circuit configured to generate distance information associated with the incident light. The color information and the distance information may be used to generate a 3D ToF color image. The ToF sensor circuit may be included under a DTI structure surrounding the plurality of pixel sensors in a top view of the pixel sensor array.

As described in greater detail above, some implementations described herein provide a pixel sensor array. The pixel sensor array includes a plurality of pixel sensors arranged in a grid. The pixel sensor array includes a DTI structure surrounding the plurality of pixel sensors in a top view of the pixel sensor array. The pixel sensor array includes a ToF sensor circuit under the DTI structure.

As described in greater detail above, some implementations described herein provide a pixel sensor array. The pixel sensor array includes a plurality of pixel sensors arranged in a grid. The pixel sensor array includes a DTI structure surrounding the plurality of pixel sensors in a top view of the pixel sensor array. The pixel sensor array includes a ToF sensor circuit under the DTI structure. The ToF sensor circuit includes a control gate and a drain gate, where a top view area of the drain gate is greater than a top view area of the control gate.

As described in greater detail above, some implementations described herein provide a method. The method includes forming a plurality of pixel sensors in a pixel sensor array on an image sensor die. The method includes forming a plurality of ToF sensor circuits around the plurality of pixel sensors on the image sensor die. The method includes bonding the image sensor die with a circuitry die after forming the plurality of pixel sensors and the plurality of ToF sensor circuits. The method includes forming, after bonding the image sensor die with the circuitry die, a DTI structure around the plurality of pixel sensors and over the plurality of ToF sensor circuits.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel sensor array, comprising:
a plurality of pixel sensors arranged in a grid;
a deep trench isolation (DTI) structure surrounding the plurality of pixel sensors in a top view of the pixel sensor array; and
a time of flight (ToF) sensor circuit under the DTI structure, the ToF sensor circuit comprising:
a first control gate on a first side of a pixel sensor of the plurality of pixel sensors;
a second control gate on a second side of the pixel sensor;
a first drain gate on a third side of the pixel sensor; and
a second drain gate on a fourth side of the pixel sensor.

2. The pixel sensor array of claim 1, wherein the pixel sensor is a first pixel sensor of the plurality of pixel sensors;
wherein the first control gate is between the first pixel sensor and a second pixel sensor of the plurality of pixel sensors;
wherein the first drain gate is between the first pixel sensor and a third pixel sensor of the plurality of pixel sensors.

3. The pixel sensor array of claim 1, wherein the first side and the second side are first opposing sides of the pixel sensor; and
wherein the third side and the fourth side are second opposing sides of the pixel sensor.

4. The pixel sensor array of claim 1, wherein the first side and the second side are first adjacent sides of the pixel sensor; and
wherein the third side and the fourth side are second adjacent sides of the pixel sensor.

5. The pixel sensor array of claim 1, wherein the ToF sensor circuit further comprises:
a first floating diffusion region at a first corner of the pixel sensor;
a second floating diffusion region at a second corner of the pixel sensor; and
a drain region at a third corner of the pixel sensor.

6. The pixel sensor array of claim 1, wherein the DTI structure surrounds subregions of each of the plurality of pixel sensors; and
wherein the ToF sensor circuit comprises:
a third control gate on a first side of a subregion of a pixel sensor of the plurality of pixel sensors;
a fourth control gate on a second side of the subregion of the pixel sensor;
a third drain gate on a third side of the subregion of the pixel sensor; and
a fourth drain gate on a fourth side of the subregion of the pixel sensor.

7. The pixel sensor array of claim 6, wherein the ToF sensor circuit further comprises:
a first floating diffusion region at a first corner of the subregion of the pixel sensor;
a second floating diffusion region at a second corner of the subregion of the pixel sensor; and
a drain region at a third corner of the subregion of the pixel sensor.

8. A pixel sensor array, comprising:
a plurality of pixel sensors arranged in a grid;
a deep trench isolation (DTI) structure surrounding the plurality of pixel sensors in a top view of the pixel sensor array; and
a time of flight (ToF) sensor circuit under the DTI structure,
wherein the ToF sensor circuit comprises:
a control gate; and
a drain gate,
wherein a top view area of the drain gate is greater than a top view area of the control gate.

9. The pixel sensor array of claim 8, wherein the control gate is at a first side of a pixel sensor of the plurality of pixel sensors;
wherein the drain gate is at a second side of the pixel sensors; and
wherein the first side and the second side are adjacent sides of the pixel sensor.

10. The pixel sensor array of claim 8, wherein the control gate is at a first side of a pixel sensor of the plurality of pixel sensors;
wherein the drain gate is at a second side of the pixel sensors; and
wherein the first side and the second side are opposing sides of the pixel sensor.

11. The pixel sensor array of claim 8, wherein the ToF sensor circuit is included around a perimeter of a 4-cell pixel sensor of the plurality of pixel sensors.

12. The pixel sensor array of claim 8, wherein the plurality of pixel sensors comprise a 4-cell quadratic phase detector (4C QPD) pixel sensor;
wherein the DTI structure surrounds a plurality of subregions of the 4C QPD pixel sensor; and
wherein the ToF sensor circuit is included around a perimeter of a subregion of the plurality of subregions of the 4C QPD pixel sensor.

13. The pixel sensor array of claim 12, wherein the ToF sensor circuit further comprises a drain region at a corner between four of the plurality of subregions of the 4C QPD pixel sensor.

14. The pixel sensor array of claim 12, wherein the ToF sensor circuit further comprises:
a first diffusion region at a corner between two of the plurality of subregions of the 4C QPD pixel sensor.

15. The pixel sensor array of claim 8, wherein the drain gate comprises:
a first p-type portion; and
an n-type portion; and
wherein the control gate comprises only a second p-type portion.

16. A method, comprising:
forming a plurality of pixel sensors in a pixel sensor array on an image sensor die;
forming a plurality of time of flight (ToF) sensor circuits around the plurality of pixel sensors on the image sensor die;
bonding the image sensor die with a circuitry die after forming the plurality of pixel sensors and the plurality of ToF sensor circuits; and
forming, after bonding the image sensor die with the circuitry die, a deep trench isolation (DTI) structure around the plurality of pixel sensors and over the plurality of ToF sensor circuits.

17. The method of claim 16, wherein forming a ToF sensor circuit of the plurality of ToF sensor circuits comprises:
forming a first doped region in a substrate of the image sensor die;
forming a doped well over the first doped region;
forming a doped guard ring around the first doped region and the doped well;
forming a second doped region over the doped well; and
forming a third doped region over the doped guard ring.

18. The method of claim 17, wherein the first doped region comprises a first p-type doped region;
wherein the doped well comprises an n-type doped well;
wherein the doped guard ring comprises a p-type doped guard ring;
wherein the second doped region comprises an n-type doped region; and
wherein the third doped region comprises a second p-type doped region.

19. The method of claim 17, wherein the first doped region comprises a first n-type doped region;
wherein the doped well comprises a p-type doped well;
wherein the doped guard ring comprises an n-type doped guard ring;
wherein the second doped region comprises a p-type doped region; and
wherein the third doped region comprises a second n-type doped region.

20. The method of claim 19, wherein forming the ToF sensor circuit further comprises:
forming a deep n-type well in the substrate,
wherein the first n-type doped region, the p-type doped well, and the n-type doped guard ring are formed in the deep n-type well.
